(19) United States
(12) Patent Application Publication
(10) Pub. No.: US 2024/0038801 A1
(43) Pub. Date: Feb. 1, 2024

(54) PHOTODETECTOR AND ELECTRONIC DEVICE

(71) Applicant: SONY SEMICONDUCTOR SOLUTIONS CORPORATION, KANAGAWA (JP)

(72) Inventor: RYOICHI NAKAMURA, KANAGAWA (JP)

(21) Appl. No.: 18/256,590

(22) PCT Filed: Dec. 9, 2021
(86) PCT No.: PCT/JP2021/045234

§ 371 Date: Jun. 8, 2023

(30) Foreign Application Priority Data
Dec. 18, 2020 (JP) 2020-210038

(51) Int. Cl. H01L 27/146; G01S 17/89

(52) U.S. Cl. CPC H01L 27/14623; G01S 17/89; H01L 27/14649; H01L 27/14634; H01L 27/14636

(57) ABSTRACT

Crosstalk is suppressed in a wiring layer. A photodetector includes a first semiconductor substrate including a first semiconductor layer in which a plurality of photoelectric conversion sections is provided in an array along a row direction and a column direction, and a first wiring layer provided on a main surface side of the first semiconductor layer, a second semiconductor substrate including a second semiconductor layer provided with an active element and a second wiring layer provided on a main surface side of the second semiconductor layer, the second wiring layer being overlapped with and joined to the first wiring layer, and a light shielding wall that divides at least one of at least a part of an interlayer insulating film of the first wiring layer or at least a part of a portion of an interlayer insulating film of the second wiring layer on a side of the first semiconductor substrate into respective portions corresponding to a first photoelectric conversion section and a second photoelectric conversion section adjacent to each other of the plurality of photoelectric conversion sections.

### TECHNICAL FIELD

The present technology (technology according to the present disclosure) relates to a photodetector and an electronic device, and particularly relates to a photodetector and an electronic device having an avalanche photodiode.

### BACKGROUND ART

An avalanche photodiode (APD) is conventionally known. The APD includes a Geiger mode in which the APD is operated at a bias voltage higher than a breakdown voltage and a linear mode in which the APD is operated at a slightly higher bias voltage near the breakdown voltage. The Geiger-mode avalanche photodiode is also called a single photon avalanche diode (SPAD). The SPAD is a device capable of detecting one photon for each pixel by multiplying a carrier generated by photoelectric conversion in a PN junction region of a high electric field provided for each pixel.

Patent Document 1 below discloses providing a separation region between the APD and the APD and providing a hole accumulation region on a side wall of the separation region in order to improve performance. Then, it discloses that electrical and optical crosstalk is further reduced.

### CITATION LIST

### Patent Document

Patent Document 1: Japanese Patent Application Laid-Open No. 2018-201005

### SUMMARY OF THE INVENTION

### Problems to be Solved by the Invention

However, a plurality of APD pixels arranged in an array may leak light to adjacent pixels via a wiring layer. Such crosstalk may cause erroneous measurement.

An object of the present technology is to provide a photodetector and an electronic device capable of suppressing crosstalk in a wiring layer.

### Solutions to Problems

A photodetector according to an aspect of the present technology includes a first semiconductor substrate including a first semiconductor layer in which a plurality of photoelectric conversion sections is provided in an array along a row direction and a column direction, and a first wiring layer provided on a main surface side of the first semiconductor layer, a second semiconductor substrate including a second semiconductor layer provided with an active element and a second wiring layer provided on a main surface side of the second semiconductor layer, the second wiring layer being overlapped with and joined to the first wiring layer, and a light shielding wall that divides at least one of at least a part of an interlayer insulating film of the first wiring layer or at least a part of a portion of an interlayer insulating film of the second wiring layer on a side of the first semiconductor substrate into respective portions corresponding to a first photoelectric conversion section and a second photoelectric conversion section adjacent to each other of the plurality of photoelectric conversion sections.

An electronic device according to another aspect of the present technology includes the photodetector described above and an optical system that forms an image of image light from a subject on the photodetector described above.

### BRIEF DESCRIPTION OF DRAWINGS

FIG. 1 is a chip layout diagram depicting a configuration example of a photodetector according to a first embodiment of the present technology.

FIG. 2 is a block diagram depicting the configuration example of the photodetector according to the first embodiment of the present technology.

FIG. 3 is an equivalent circuit diagram depicting a configuration example of a pixel.

FIG. 4 is a cross-sectional view depicting a cross-sectional structure taken along line A-A in FIG. 2.

FIG. 5 is a cross-sectional view depicting a main part of FIG. 2.

FIG. 6A is a cross-sectional view depicting a cross-sectional structure taken along line B-B in FIG. 5.

FIG. 6B is a cross-sectional view depicting a cross-sectional structure taken along line C-C in FIG. 5.

FIG. 6C is a cross-sectional view depicting a cross-sectional structure taken along line D-D in FIG. 5.

FIG. 6D is a cross-sectional view depicting a cross-sectional structure taken along line E-E in FIG. 5.

FIG. 7 is a cross-sectional view depicting a main part of a photodetector according to a first modification of the first embodiment of the present technology.

FIG. 8A is a cross-sectional view depicting a cross-sectional structure taken along line F-F in FIG. 7.

FIG. 8B is a cross-sectional view depicting a cross-sectional structure taken along line G-G in FIG. 7.

FIG. 9 is a cross-sectional view depicting a main part of a photodetector according to a second modification of the first embodiment of the present technology.

FIG. 10 is a cross-sectional view depicting a cross-sectional structure taken along line H-H in FIG. 9.

FIG. 11 is a cross-sectional view depicting a main part of a photodetector according to a third modification of the first embodiment of the present technology.

FIG. 12A is a cross-sectional view depicting a cross-sectional structure taken along line I-I in FIG. 11.

FIG. 12B is a cross-sectional view depicting a cross-sectional structure taken along line J-J in FIG. 11.

FIG. 13 is a cross-sectional view depicting a main part of a photodetector according to a fourth modification of the first embodiment of the present technology.

FIG. 14 is a cross-sectional view depicting a main part of a photodetector according to a second embodiment of the present technology.

FIG. 15A is a cross-sectional view depicting a cross-sectional structure taken along line K-K in FIG. 14.

FIG. 15B is a cross-sectional view depicting a cross-sectional structure taken along line L-L in FIG. 14.

FIG. 15C is a cross-sectional view depicting a cross-sectional structure taken along line M-M in FIG. 14.

FIG. 15D is a cross-sectional view depicting a cross-sectional structure taken along line N-N in FIG. 14.

FIG. 16 is a cross-sectional view depicting a main part of a photodetector according to a first modification of the second embodiment of the present technology.

FIG. 17A is a cross-sectional view depicting a cross-sectional structure taken along line O-O in FIG. 16.

FIG. 17B is a cross-sectional view depicting a cross-sectional structure taken along line P-P in FIG. 16.

FIG. 18 is a cross-sectional view depicting a main part of a photodetector according to a second modification of the second embodiment of the present technology.

FIG. 19A is a cross-sectional view depicting a cross-sectional structure taken along line Q-Q in FIG. 18.

FIG. 19B is a cross-sectional view depicting a cross-sectional structure taken along line R-R and line X-X in FIG. 18.

FIG. 19C is a cross-sectional view depicting a cross-sectional structure taken along line S-S in FIG. 18.

FIG. 19D is a cross-sectional view depicting a cross-sectional structure taken along line T-T in FIG. 18.

FIG. 20 is a block diagram depicting a configuration example of a distance image device according to a third embodiment using a photodetector of the present technology.

FIG. 21 is a block diagram depicting an example of schematic configuration of a vehicle control system.

FIG. 22 is a diagram of assistance in explaining an example of installation positions of an outside-vehicle information detecting section and an imaging section.

FIG. 23 is a view depicting an example of a schematic configuration of an endoscopic surgery system.

FIG. 24 is a block diagram depicting an example of a functional configuration of a camera head and a camera control unit (CCU).

### MODE FOR CARRYING OUT THE INVENTION

Hereinafter, preferred embodiments for carrying out the present technology will be described with reference to the drawings. Note that embodiments hereinafter described each depict an example of a representative embodiment of the present technology, and the scope of the present technology is not narrowed by them.

In the following drawings, the same or similar parts are denoted by the same or similar reference numerals. Meanwhile, it should be noted that the drawings are schematic, and a relationship between a thickness and planar dimensions, a ratio of the thicknesses between layers, and the like are different from actual ones. Therefore, specific thicknesses and dimensions should be determined in consideration of the following description. Furthermore, it is needless to say that the drawings include portions having different dimensional relationships and ratios.

Furthermore, the first to third embodiments described below each depict an example of a device and a method for embodying the technical idea of the present technology, and the technical idea of the present technology does not limit the material, shape, structure, arrangement, and the like of components to the following. Various modifications can be made to the technical idea of the present technology within the technical scope defined by the claims described in the claims.

The description will be made in the following order.
1. First Embodiment
2. First Modification of First Embodiment
3. Second Modification of First Embodiment
4. Third Modification of First Embodiment
5. Fourth Modification of First Embodiment
6. Second Embodiment
7. First Modification of Second Embodiment
8. Second Modification of Second Embodiment
9. Third Embodiment

### First Embodiment

<Overall Configuration of Photodetector>

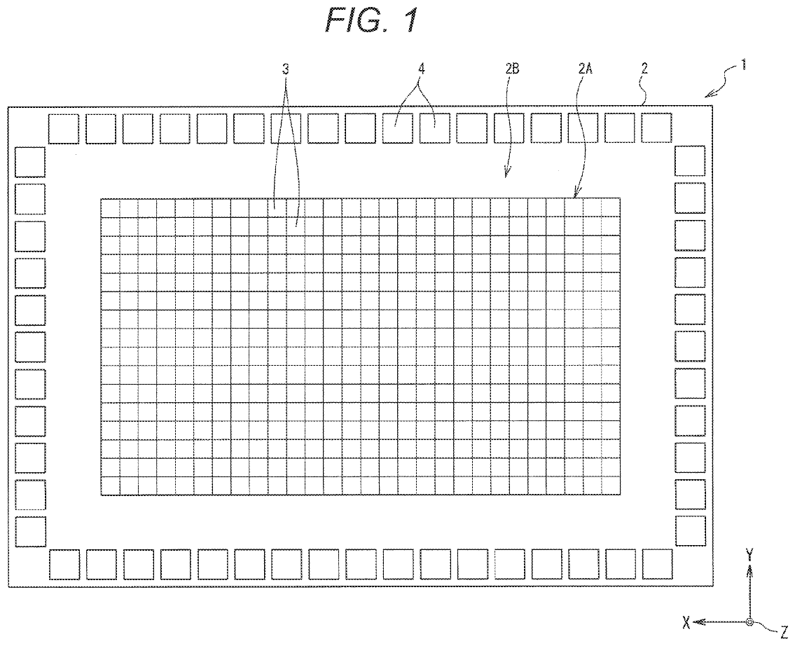

In the present embodiment, an example in which the present technology is applied to a photodetector that is a back-illuminated complementary metal oxide semiconductor (CMOS) image sensor will be described. As depicted in FIG. 1, a photodetector 1 according to a first embodiment of the present technology mainly includes a sensor chip 2 having a rectangular two-dimensional planar shape in plan view. That is, the photodetector 1 is mounted on the sensor chip 2. The sensor chip 2 includes a rectangular pixel region 2A arranged in a central portion in a two-dimensional plane, and a peripheral region 2B arranged outside the pixel region 2A so as to surround the pixel region 2A.

The pixel region 2A is a light receiving surface that receives light condensed by an optical system that is not depicted. Then, as depicted in FIG. 1, in the pixel region 2A, a plurality of pixels 3 is provided in an array along a row direction (X direction) and a column direction (Y direction) intersecting the row direction. Each pixel 3 includes a photoelectric conversion section that performs photoelectric conversion. Furthermore, a thickness direction of the sensor chip 2 is parallel to the Z direction. The X direction and the Y direction are orthogonal to each other in the example of FIG. 1, but may intersect each other, and are not limited to orthogonal. The Z direction is orthogonal to the X direction and the Y direction.

A plurality of electrode pads 4 is disposed in the peripheral region 2B. Each of the plurality of electrode pads 4 is arranged, for example, along four sides in a two-dimensional plane of the sensor chip 2. Each of the plurality of electrode pads 4 is an input/output terminal used when the sensor chip 2 is electrically connected to an external device that is not depicted.

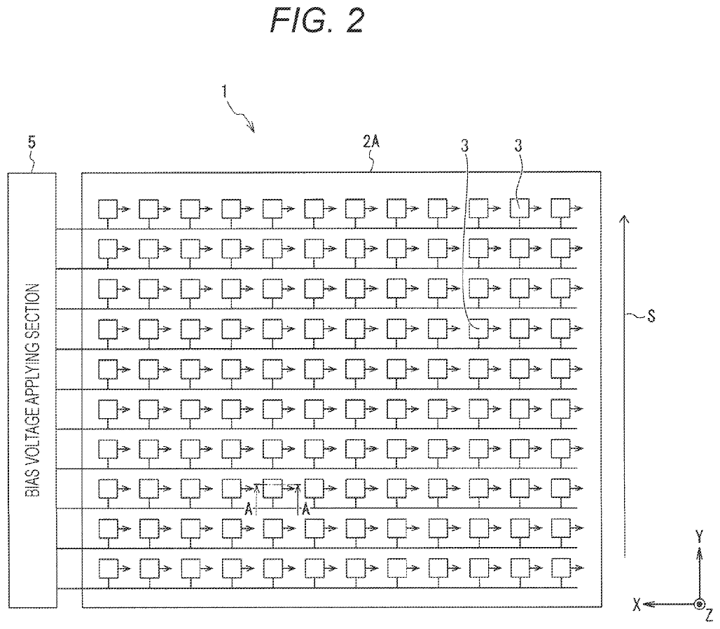

As depicted in FIG. 2, the sensor chip 2 includes a bias voltage applying section 5 together with the pixel region 2A. The bias voltage applying section 5 applies a bias voltage to each of the plurality of pixels 3 arranged in the pixel region 2A. Specifically, the bias voltage applying section 5 applies a bias voltage to a plurality of pixels 3 provided in an array in units of rows (X direction). Then, the bias voltage applying section 5 applies a bias voltage to the row sequentially selected along the column direction (Y direction). The column direction is a scanning direction. An arrow S in FIG. 2 indicates an example of the scan direction. The scanning direction may be a direction opposite to the arrow S in FIG. 2.

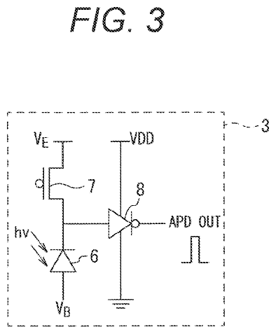

FIG. 3 is a diagram depicting a configuration example of an equivalent circuit of the pixel 3. As depicted in FIG. 3, each pixel 3 includes, for example, an avalanche photodiode (APD) element 6 as a photoelectric conversion element, a quenching resistance element 7 including, for example, a p-type metal oxide semiconductor field effect transistor (MOSFET), and an inverter 8 including, for example, a complementary MOSFET (complementary MOS).

The APD element 6 has an anode connected to the bias voltage applying section 5 and a cathode connected to a source terminal of the quenching resistance element 7. A bias voltage VB is applied from the bias voltage applying section 5 to the anode of the APD element 6. The APD element 6 is a photoelectric conversion element that forms an avalanche multiplication region (depletion layer) when a large negative voltage is applied to the cathode and capable of performing avalanche multiplication of electrons generated by incidence of one photon.

The quenching resistance element 7 is connected in series with the APD element 6, and has a source terminal connected to the cathode of the APD element 6, and a drain terminal connected to a power supply that is not depicted. An excitation voltage VE is applied from a power supply to a drain terminal of the quenching resistance element 7. When the voltage caused by the electrons avalanche multiplied by the APD element 6 reaches a negative voltage VBD, the quenching resistance element 7 performs quenching to emit the electrons multiplied by the APD element 6 and return the voltage to the initial voltage.

The inverter 8 has an input terminal connected to the cathode of the APD element 6 and the source terminal of the quenching resistance element 7, and an output terminal connected to an arithmetic processing unit in a subsequent stage that is not depicted. The inverter 8 outputs a light reception signal on the basis of the electrons multiplied by the APD element 6. More specifically, the inverter 8 shapes the voltage generated by the electrons multiplied by the APD element 6. Then, the inverter 8 outputs, to the arithmetic processing unit, a light reception signal (APD OUT) in which a pulse waveform depicted in FIG. 3 is generated, for example, with the arrival time of one photon as a starting point. For example, the arithmetic processing unit performs arithmetic processing of obtaining the distance to a subject on the basis of a timing at which a pulse indicating an arrival time of one photon is generated in each light reception signal, and obtains the distance for each pixel 3. Then, on the basis of the distances, a distance image is generated in which the distances to the subject detected by the plurality of pixels 3 are planarly arranged.

<Configuration of Sensor Chip>

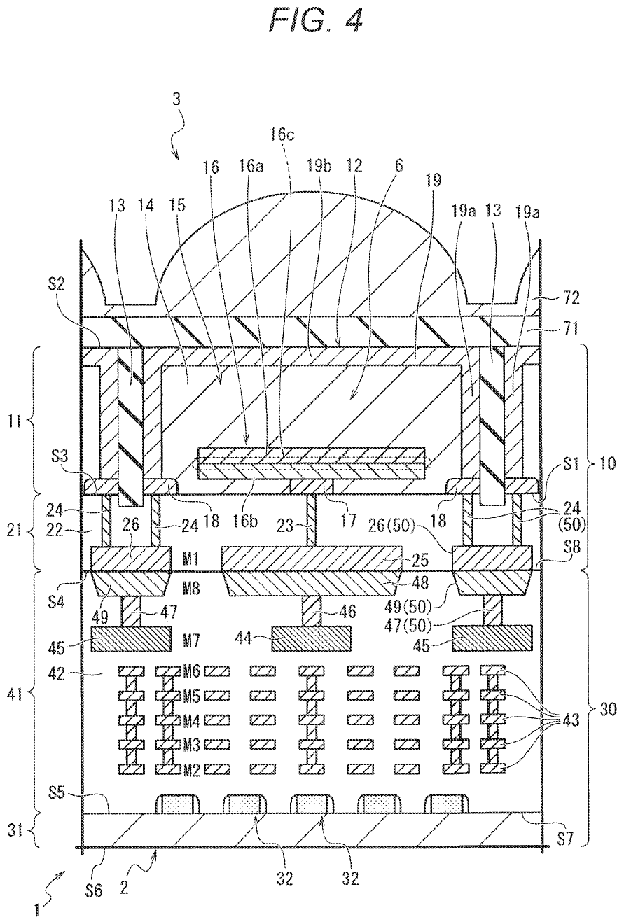

FIG. 4 is a cross-sectional view taken along a cutting line passing through the central portion of the pixel 3. As depicted in FIG. 4, the sensor chip 2 includes a first semiconductor substrate (photoelectric conversion substrate part) 10 and a second semiconductor substrate (circuit substrate part) 30 that are joined to face each other. The above-described pixel region 2A is formed in the first semiconductor substrate 10. The second semiconductor substrate 30 includes the bias voltage applying section 5, the quenching resistance element 7, the inverter 8, and the electrode pads 4 described above, a reading circuit that outputs a pixel signal based on charges output from the pixel 3 in the pixel region 2A, and a logic circuit including at least a part of a vertical drive circuit, a column signal processing circuit, a horizontal drive circuit, an output circuit, and the like. Further, the sensor chip 2 includes a planarization film 71 and a microlens layer 72. Furthermore, the sensor chip 2 includes a light shielding wall 50.

The first semiconductor substrate 10 includes a first semiconductor layer 11 and a first wiring layer 21. The first semiconductor layer 11 has a first surface S1 and a second surface S2 located on opposite sides in the thickness direction (Z direction). Here, the first surface S1 may be referred to as an element formation surface or a main surface, and the second surface S2 may be referred to as a light incident surface or a back surface. The first wiring layer 21 is provided on the first surface S1 side of the first semiconductor layer 11, and the planarization film 71 and the microlens layer 72 are stacked in this order on the second surface S2 side. The first wiring layer 21 has a third surface S3 and a fourth surface S4 located on opposite sides in the thickness direction. The third surface S3 is a surface on the first semiconductor layer 11 side and is in contact with the first surface S1. The fourth surface S4 is a surface opposite to the surface on the first semiconductor layer 11 side (third surface S3).

The second semiconductor substrate 30 includes a second semiconductor layer 31 and a second wiring layer 41. The second semiconductor layer 31 has a fifth surface S5 and a sixth surface S6 located on opposite sides in the thickness direction. Here, the fifth surface S5 may be referred to as an element formation surface or a main surface, and the sixth surface S6 may be referred to as a back surface. The second wiring layer 41 is provided on the fifth surface S5 side of the second semiconductor layer 31. The second wiring layer 41 has a seventh surface S7 and an eighth surface S8 located on opposite sides in the thickness direction. The seventh surface S7 is a surface on the second semiconductor layer 31 side and is in contact with the fifth surface S5. The eighth surface S8 is a surface opposite to the surface on the second semiconductor layer 31 side (the seventh surface S7).

The first semiconductor substrate 10 and the second semiconductor substrate 30 are joined by overlapping and joining the respective wiring layers. Specifically, the first semiconductor substrate 10 and the second semiconductor substrate 30 are overlapped and joined by joining the fourth surface S4 of the first wiring layer 21 and the eighth surface S8 of the second wiring layer 41. Then, the first semiconductor substrate 10 and the second semiconductor substrate 30 are also electrically connected.

The light shielding wall 50 is provided over both the first wiring layer 21 of the first semiconductor substrate 10 and the second wiring layer 41 of the second semiconductor substrate 30.

<Configuration of First Semiconductor Substrate>

(Configuration of First Semiconductor Layer)

As depicted in FIG. 4, the first semiconductor layer 11 includes a photoelectric conversion section 12 and a separation portion 13. First, the separation portion 13 will be described. The separation portion 13 extends in the thickness direction of the first semiconductor layer 11. The separation portion 13 electrically and optically separates the adjacent photoelectric conversion sections 12 from each other. The separation portion 13 has a single-layer structure including silicon oxide (SiO₂) or a multilayer structure in which both sides of a metal film are sandwiched between insulating films, for example.

Next, the photoelectric conversion section 12 will be described. The photoelectric conversion section 12 includes the APD element 6 described above. The photoelectric conversion section 12 includes a well region 14, and a light absorption section 15 and a multiplication section 16 sequentially provided in the well region 14 along the thickness direction. The light absorption section 15 is located closer to the second surface S2 side than the multiplication section 16 in the thickness direction.

Furthermore, the photoelectric conversion section 12 includes a first contact region 17 provided to be electrically connected to a second electrode region 16b to be described later, and a second contact region 18 provided to be electrically connected to a first electrode region 16a to be described later.

Furthermore, the photoelectric conversion section 12 includes a charge accumulation region 19 electrically connected to the well region 14 and the second contact region 18.

The light absorption section 15 is a photoelectric conversion region that is mainly configured by the well region 14 and absorbs light incident from the second surface S2 side (light incident surface side) to generate electrons (carriers). Then, the light absorption section 15 transfers electrons generated by photoelectric conversion to the multiplication section 16 by an electric field. The well region 14 may be p-type or n-type, but will be described as p-type here. The well region 14 includes a p-type semiconductor region having the lowest impurity concentration in the semiconductor regions of the photoelectric conversion section 12.

The multiplication section 16 performs avalanche multiplication on the electrons transferred from the light absorption section 15. The multiplication section 16 includes a first electrode region 16a of a first conductivity type (for example, p-type) and a second electrode region 16b of a second conductivity type (for example, n-type). The first conductivity type is one of p-type and n-type, and the second conductivity type is the other of the p-type and the n-type. Here, the first conductivity type is p-type, and the second conductivity type is an n-type. A junction between the first electrode region 16a and the second electrode region 16b forms a pn junction. An avalanche multiplication region 16c is formed at an interface portion of the pn junction. The first electrode region 16a is provided closer to the second surface S2 side than the second electrode region 16b in the thickness direction. The p-type first electrode region 16a include a p-type semiconductor region having a higher impurity concentration than the p-type well region 14, and the n-type second electrode region 16b includes an n-type semiconductor region having a higher impurity concentration than the p-type well region 14.

The avalanche multiplication region 16c is a high electric field region (depletion layer) formed at the interface portion of the pn junction between the p-type first electrode region 16a and the n-type second electrode region 16b by a large negative voltage applied to the n-type second electrode region 16b, and multiplies electrons (e−) generated by one photon incident on the photoelectric conversion section 12. The multiplied electrons are sent to the first contact region 17.

The charge accumulation region 19 of the first conductivity type (p-type) has a first portion 19a and a second portion 19b. The first portion 19a is provided along the wall surface of the separation portion 13. The second portion 19b is provided along the second surface S2 side. That is, the charge accumulation region 19 is provided such that the first portion 19a in contact with a side surface of the well region 14 and the second portion 19b in contact with a surface closer to the second surface S2 among surfaces of the well region 14 surround the well region 14.

The p-type charge accumulation region 19 includes a p-type semiconductor region having a higher impurity concentration than the p-type well region 14 and the p-type first electrode region 16a, and accumulates positive holes (holes) as carriers. The charge accumulation region 19 is electrically connected to the second contact region 18 functioning as an anode, and enables bias adjustment. Thus, hole concentration in the charge accumulation region 19 is enhanced and pinning is strengthened, whereby generation of dark current can be suppressed, for example.

The first conductivity type (p-type) second contact region 18 is provided so as to surround an outer periphery of the well region 14 and overlap the first portion 19a of the p-type charge accumulation region 19 in a surface layer portion on the first surface S1 side. The p-type second contact region 18 includes a p-type semiconductor region having a higher impurity concentration than the p-type first electrode region 16a. The second contact region 18 reduces ohmic contact resistance with a contact electrode wiring 24 described later and functions as an anode. The second contact region 18 is electrically connected to the bias voltage applying section 5, and the bias voltage VB is applied thereto.

The second conductivity type (n-type) first contact region 17 is provided between the first surface S1 and the n-type second electrode region 16b. The n-type first contact region 17 includes an n-type semiconductor region having a higher impurity concentration than the n-type second electrode region 16b, reduces ohmic contact resistance with a contact electrode 23 described later, and functions as a cathode. The first contact region 17 outputs electrons multiplied in the avalanche multiplication region 16c from the first semiconductor layer 11.

(Configuration of First Wiring Layer)

As depicted in FIG. 4, the first wiring layer 21 has a one-layer wiring structure in which a first connection pad 25 and a first connection wiring 26 by one layer of metal M1 are stacked with a first interlayer insulating film (insulating film) 22 interposed therebetween. The first connection pad 25 and the first connection wiring 26 face the fourth surface S4 of the first wiring layer 21. The first connection pad 25 and the first connection wiring 26 are formed using metal such as copper (Cu), for example. The first connection pad 25 also functions as a reflector that reflects light incident from the light incident surface side.

Furthermore, the contact electrode 23 and the contact electrode wiring 24 are provided in the first interlayer insulating film 22 between the first semiconductor layer 11 and the metal M1. The contact electrode 23 and the contact electrode wiring 24 are formed using metal such as tungsten or cobalt. Here, a description will be given assuming that tungsten is used. The contact electrode 23 has one end joined to the first contact region 17 and the other end joined to the first connection pad 25. The contact electrode wiring 24 has one end joined to the second contact region 18 and the other end joined to the first connection wiring 26.

<Configuration of Second Semiconductor Substrate>

(Configuration of Second Semiconductor Layer)

As depicted in FIG. 4, a channel region of a plurality of MOSFETs 32 is formed in the second semiconductor layer 31 of the second semiconductor substrate 30. The MOSFET 32 is a field effect transistor (active element) constituting a circuit including at least a part of the bias voltage applying section 5, the reading circuit, the logic circuit, and the like. As the second semiconductor layer 31, for example, a semiconductor substrate including single crystal silicon is used.

(Configuration of Second Wiring Layer)

The second wiring layer 41 has a multilayer wiring structure in which a wiring 43 including five layers of metals M2 to M6, an electrode pad 44 and an electrode pad 45 of one layer of metal M7, and a second connection pad 48 and a second connection wiring 49 of one layer of metal M8 are stacked in this order from the seventh surface S7 side with a second interlayer insulating film (insulating film) 42 interposed therebetween.

The second connection pad 48 and the second connection wiring 49, which are the metal M8, face the eighth surface S8 of the second wiring layer 41. The second connection pad 48 and the second connection wiring 49 are formed using metal such as copper (Cu), for example. A surface of the second connection pad 48 facing the eighth surface S8 is joined to the first connection pad 25, and a surface of the second connection wiring 49 facing the eighth surface S8 is joined to the first connection wiring 26. The second connection pad 48 is formed by a dual damascene method together with a second via electrode 46 described later, for example. Moreover, the second connection wiring 49 is formed by a dual damascene method together with a second via electrode wiring 47 described later, for example. Furthermore, the second connection pad 48 forms a reflector together with the first connection pad 25.

The electrode pad 44 and the electrode pad 45, which are the metal M7, are formed using metal such as aluminum (Al) or copper (Cu), for example. Here, a description will be given assuming that aluminum (Al) is used. The bias voltage VB is supplied to the electrode pad 45 by the bias voltage applying section 5. The bias voltage VB may be supplied to the electrode pad 45 via, for example, at least one of a via that is not depicted or the wiring 43.

The second via electrode 46 and the second via electrode wiring 47 are provided in the second interlayer insulating film 42 between the metal M8 and the metal M7. The second via electrode 46 and the second via electrode wiring 47 are formed using metal such as copper (Cu), for example. The second via electrode 46 has one end joined to the second connection pad 48 and the other end joined to the electrode pad 44. The second via electrode wiring 47 has one end joined to the second connection wiring 49 and the other end joined to the electrode pad 45.

The wiring 43 is electrically connected to the wiring 43 of a different wiring layer via a via electrode embedded in the second interlayer insulating film 42. Furthermore, the wiring 43 is connected to the second semiconductor layer 31 via a contact electrode that is not depicted. Moreover, the wiring 43 may be connected to the electrode pad 44 and the electrode pad 45 via a via electrode that is not depicted.

<Configuration of Conductive Path>

The first contact region 17 is electrically connected to the electrode pad 44 via the contact electrode 23, the first connection pad 25, the second connection pad 48, and the second via electrode 46. With such a structure, electrons flow from the first contact region 17 to the electrode pad 44 via the contact electrode 23, the first connection pad 25, the second connection pad 48, and the second via electrode 46. At least a part of the first connection pad 25, the second connection pad 48, and the second via electrode 46 provided between the contact electrode 23 and the electrode pad 44 functions as a reading electrode that outputs carriers from the APD element 6 of the first semiconductor substrate 10 to the second semiconductor substrate 30. Furthermore, the reading electrode is provided over the first wiring layer 21 and the second wiring layer 41.

Furthermore, the second contact region 18 is electrically connected to the electrode pad 45 via the contact electrode wiring 24, the first connection wiring 26, the second connection wiring 49, and the second via electrode wiring 47. With such a structure, the bias voltage VB supplied to the electrode pad 45 is supplied to the second contact region 18 via the second via electrode wiring 47, the second connection wiring 49, the first connection wiring 26, and the contact electrode wiring 24.

<Configuration of Light Shielding Wall>

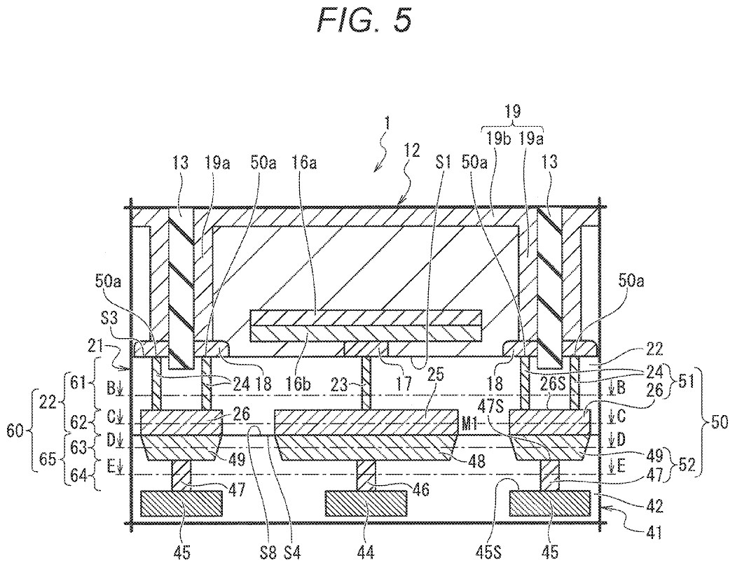

FIG. 5 is a diagram depicting a main part of FIG. 4. The light shielding wall 50 includes the contact electrode wiring 24, the first connection wiring 26, the second connection wiring 49, and the second via electrode wiring 47. The light shielding wall 50 has a function of supplying the bias voltage VB from the second semiconductor substrate 30 side to the first semiconductor substrate 10 side, and has a function of suppressing crosstalk between two adjacent photoelectric conversion sections 12. Further, the light shielding wall 50 is provided between the adjacent reading electrodes. Furthermore, the light shielding wall 50 is provided so as to surround one reading electrode.

(Contact Electrode Wiring)

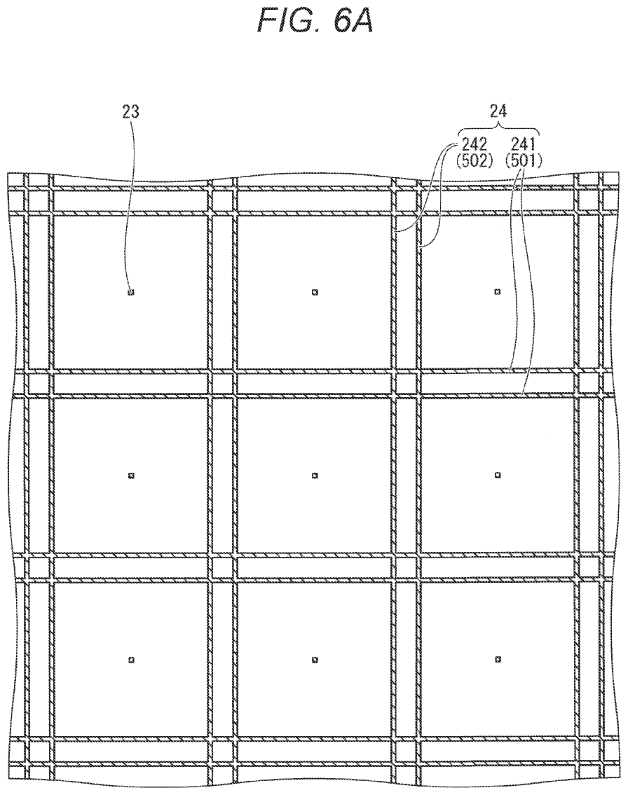

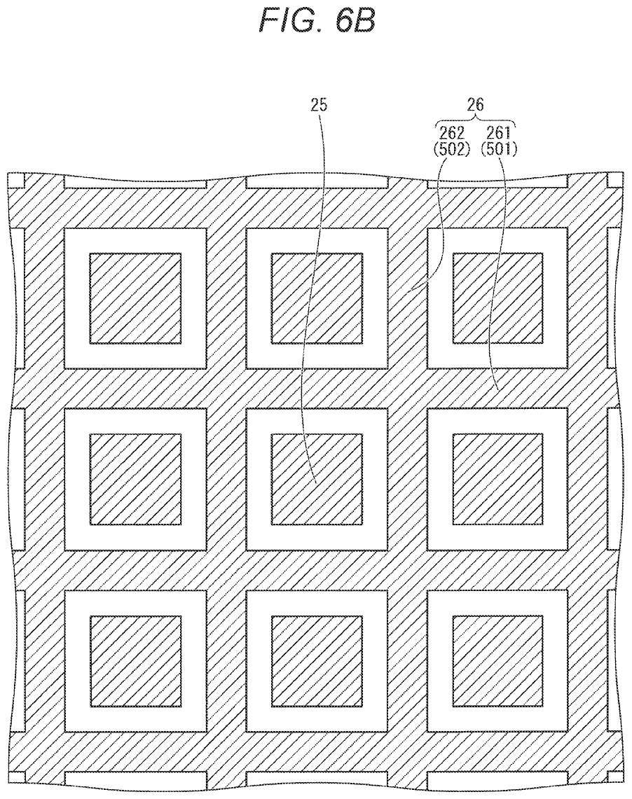

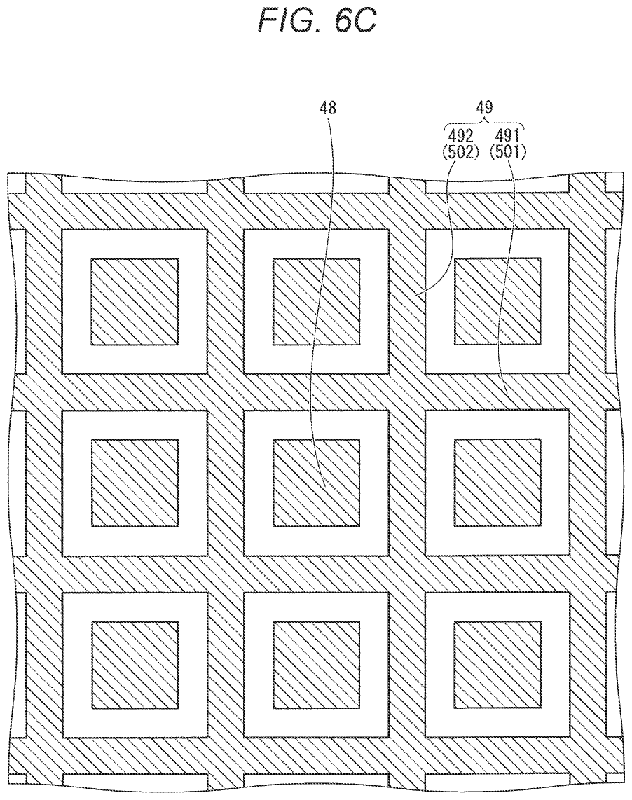

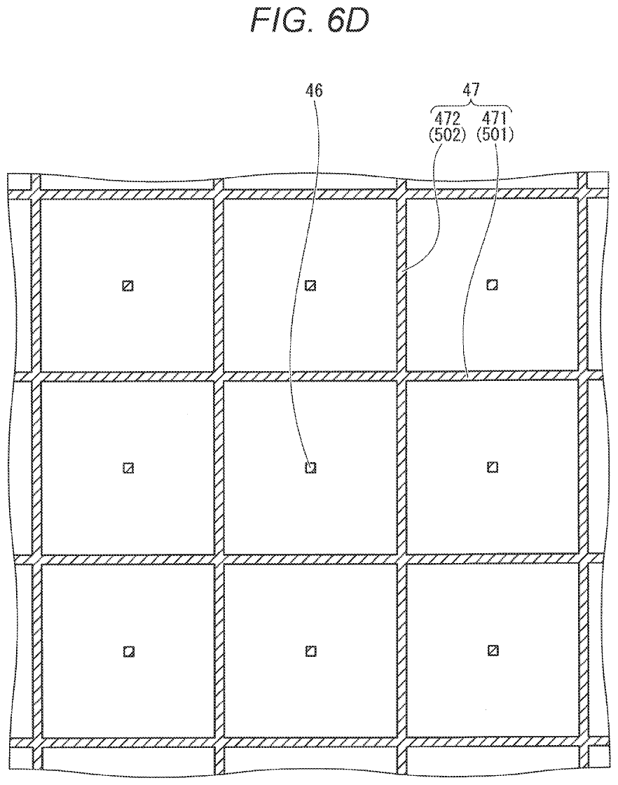

FIG. 6A is a cross-sectional view depicting a cross-sectional structure taken along a B-B cutting line in FIG. 5. Note that the B-B cutting line in FIG. 5 is depicted as a cutting line for the portion corresponding to one photoelectric conversion section 12, but the cross-sectional view depicted in FIG. 6A includes a cross-sectional structure of the portion corresponding to a plurality of photoelectric conversion sections 12. Hereinafter, the cross-sectional structure along the cutting line is the same. As depicted in the cross-sectional view of FIG. 6A, the contact electrode wiring 24 is a mesh-like wiring obtained by extending a conventional through hole electrode along the row direction or the column direction. Specifically, the contact electrode wiring 24 is provided by forming grooves in the first interlayer insulating film 22 and filling the groove with metal. As depicted in FIG. 5, the contact electrode wiring 24 penetrates a portion of the first interlayer insulating film 22 in the thickness direction, the portion extending and stacked on an X-Y plane between the third surface S3 and the surface 26S that is a surface of the first connection wiring 26 on the first semiconductor layer 11 side. Here, the interlayer insulating film divided by the contact electrode wiring 24 is referred to as an interlayer insulating film 61 in order to distinguish it from other interlayer insulating films. Specifically, the contact electrode wiring 24 divides the interlayer insulating film 61 into respective portions corresponding to the two adjacent photoelectric conversion sections 12. That is, the contact electrode wiring 24 is a light shielding wall (first light shielding wall) that divides the interlayer insulating film 61. The interlayer insulating film 61 is a part of the interlayer insulating film included in the first wiring layer 21. Furthermore, the contact electrode wiring 24 is provided between the adjacent reading electrodes, that is, between the adjacent contact electrodes 23.

As depicted in FIG. 6A, the contact electrode wiring 24 includes a first portion 241 extending along both the thickness direction and the row direction, and a second portion 242 extending along both the thickness direction and the column direction. The first portion 241 divides the interlayer insulating film 61 into respective portions corresponding to the two photoelectric conversion sections 12 adjacent to each other in the column direction. The second portion 242 divides the interlayer insulating film 61 into respective portions corresponding to the two photoelectric conversion sections 12 adjacent to each other in the row direction. As described above, the contact electrode wiring 24 is provided so as to surround one contact electrode 23 by the first portion 241 and the second portion 242.

(First Connection Wiring)

As depicted in the cross-sectional view of FIG. 6B, the first connection wiring 26 is a mesh-like wiring obtained by extending a pad electrode having a conventional quadrangular shape along the row direction or the column direction. Specifically, the first connection wiring 26 is provided by forming grooves in the first interlayer insulating film 22 and filling the groove with metal. As depicted in FIG. 5, the first connection wiring 26 penetrates a portion of the first interlayer insulating film 22 in the thickness direction, the portion extending and stacked on an X-Y plane between the surface 26S and the fourth surface S4. Here, the interlayer insulating film divided by the first connection wiring 26 is referred to as an interlayer insulating film 62 in order to distinguish it from other interlayer insulating films. Specifically, the first connection wiring 26 divides the interlayer insulating film 62 into respective portions corresponding to the two adjacent photoelectric conversion sections 12. That is, the first connection wiring 26 is a light shielding wall (second light shielding wall) that divides the interlayer insulating film 62. The interlayer insulating film 62 is a part of the interlayer insulating film included in the first wiring layer 21. Furthermore, the first connection wiring 26 is provided between the adjacent reading electrodes, that is, between the adjacent first connection pads 25.

As depicted in FIG. 6B, the first connection wiring 26 includes a first portion 261 extending along both the thickness direction and the row direction, and a second portion 262 extending along both the thickness direction and the column direction. The first portion 261 divides the interlayer insulating film 62 into respective portions corresponding to the two photoelectric conversion sections 12 adjacent to each other in the column direction. The second portion 262 divides the interlayer insulating film 62 into respective portions corresponding to the two photoelectric conversion sections 12 adjacent to each other in the row direction. Furthermore, the first connection wiring 26 is provided so as to surround one first connection pad 25 by the first portion 261 and the second portion 262.

(Second Connection Wiring)

As depicted in the cross-sectional view of FIG. 6C, the second connection wiring 49 is a mesh-like wiring obtained by extending a pad electrode having a conventional quadrangular shape along the row direction or the column direction. Specifically, the second connection wiring 49 is provided by forming grooves in the second interlayer insulating film 42 and filling the groove with metal. As depicted in FIG. 5, the second connection wiring 49 penetrates a portion of the second interlayer insulating film 42 in the thickness direction, the portion extending and stacked on an X-Y plane between the eighth surface S8 and the surface 47S that is a surface of the second via electrode wiring 47 on the first semiconductor substrate 10 side. Here, the interlayer insulating film divided by the second connection wiring 49 is referred to as an interlayer insulating film 63 in order to distinguish it from other interlayer insulating films. Specifically, the second connection wiring 49 divides the interlayer insulating film 63 into respective portions corresponding to the two adjacent photoelectric conversion sections 12. That is, the second connection wiring 49 is a light shielding wall (third light shielding wall) that divides the interlayer insulating film 63. The interlayer insulating film 63 is a part of an upper interlayer insulating film included in the second wiring layer 41. Furthermore, the second connection wiring 49 is provided between the adjacent reading electrodes, that is, between the adjacent second connection pads 48.

Here, in the second interlayer insulating film 42, the interlayer insulating film extending and stacked on an X-Y plane between the eighth surface S8 and the surface 45S that is a surface of the electrode pad 45 on the first semiconductor substrate 10 side is referred to as the upper interlayer insulating film (a portion of the second interlayer insulating film 42 on the first semiconductor substrate 10 side) in order to distinguish the interlayer insulating film from other interlayer insulating films. Such an interlayer insulating film is referred to as the upper interlayer insulating film in order to distinguish it from other interlayer insulating films, particularly, in order to distinguish it from an interlayer insulating film stacked between a surface of the electrode pad 45 opposite to the surface 45S and the seventh surface S7.

As depicted in FIG. 6C, the second connection wiring 49 includes a first portion 491 extending along both the thickness direction and the row direction, and a second portion 492 extending along both the thickness direction and the column direction. The first portion 491 divides the interlayer insulating film 63 into respective portions corresponding to the two photoelectric conversion sections 12 adjacent to each other in the column direction. The second portion 492 divides the interlayer insulating film 63 into respective portions corresponding to the two photoelectric conversion sections 12 adjacent to each other in the row direction. Furthermore, the second connection wiring 49 is provided so as to surround one second connection pad 48 by the first portion 491 and the second portion 492.

(Second Via Electrode Wiring)

As depicted in the cross-sectional view of FIG. 6D, the second via electrode wiring 47 is a mesh-like wiring obtained by extending a conventional through hole electrode along the row direction or the column direction. Specifically, the second via electrode wiring 47 is provided by forming grooves in the second interlayer insulating film 42 and filling the groove with metal. As depicted in FIG. 5, the second via electrode wiring 47 penetrates a portion of the second interlayer insulating film 42 in the thickness direction, the portion extending and stacked on an X-Y plane between the surface 47S and the surface 45S. Here, the interlayer insulating film divided by the second via electrode wiring 47 is referred to as an interlayer insulating film 64 in order to distinguish it from other interlayer insulating films. Specifically, the second via electrode wiring 47 divides the interlayer insulating film 64 into respective portions corresponding to the two adjacent photoelectric conversion sections 12. That is, the second via electrode wiring 47 is a light shielding wall (fourth light shielding wall) that divides the interlayer insulating film 64. The interlayer insulating film 64 is a part of the upper interlayer insulating film included in the second wiring layer 41. Furthermore, the second via electrode wiring 47 is provided between the adjacent reading electrodes, that is, between the adjacent second via electrodes 46.

As depicted in FIG. 6D, the second via electrode wiring 47 includes a first portion 471 extending along both the thickness direction and the row direction, and a second portion 472 extending along both the thickness direction and the column direction. The first portion 471 divides the interlayer insulating film 64 into respective portions corresponding to the two photoelectric conversion sections 12 adjacent to each other in the column direction. The second portion 472 divides the interlayer insulating film 64 into respective portions corresponding to the two photoelectric conversion sections 12 adjacent to each other in the row direction. Furthermore, the second via electrode wiring 47 is provided so as to surround one second via electrode 46 by the first portion 471 and the second portion 472. The second via electrode wiring 47 has been described above.

Since the contact electrode wiring 24, the first connection wiring 26, the second connection wiring 49, and the second via electrode wiring 47 as described above are overlapped and joined in this order, the light shielding wall 50 penetrates the interlayer insulating film 61 through the interlayer insulating film 64 in the thickness direction. Here, the interlayer insulating film 61 to the interlayer insulating film 64 are collectively referred to as an interlayer insulating film 60. Specifically, the light shielding wall 50 divides the interlayer insulating film 60 into respective portions corresponding to the two adjacent photoelectric conversion sections 12.

Note that, as depicted in FIG. 5, the interlayer insulating film 61 and the interlayer insulating film 62 are collectively referred to as the first interlayer insulating film 22. Furthermore, the interlayer insulating film 63 and the interlayer insulating film 64 described above are collectively referred to as an interlayer insulating film 65 in order to distinguish them from the other second interlayer insulating films 42. The interlayer insulating film 65 corresponds to the upper interlayer insulating film.

Furthermore, the light shielding wall 50 includes a first portion 501 extending along both the thickness direction and the row direction, and a second portion 502 extending along both the thickness direction and the column direction. Since the light shielding wall 50 includes the contact electrode wiring 24, the first connection wiring 26, the second connection wiring 49, and the second via electrode wiring 47, the first portion 501 includes the first portions 241, 261, 491, and 471. Similarly, the second portion 502 includes the second portions 242, 262, 492, and 472.

Furthermore, the contact electrode wiring 24, the first connection wiring 26, the second connection wiring 49, and the second via electrode wiring 47 are formed using metal as described above. Thus, each of the contact electrode wiring 24, the first connection wiring 26, the second connection wiring 49, and the second via electrode wiring 47 does not pass light in a wavelength band that can be photoelectrically converted by the photoelectric conversion section 12. For example, in a case where the photoelectric conversion section 12 photoelectrically converts infrared light having a wavelength of about 900 nm to 940 nm, each of the contact electrode wiring 24, the first connection wiring 26, the second connection wiring 49, and the second via electrode wiring 47 does not pass the wavelength in the band. Furthermore, for example, in a case where the photoelectric conversion section 12 photoelectrically converts visible light, the wirings do not pass the wavelength in the band.

Since the contact electrode wiring 24, the first connection wiring 26, the second connection wiring 49, and the second via electrode wiring 47 as described above are overlapped and joined in this order, the light shielding wall 50 does not pass light in the wavelength band that can be photoelectrically converted by the photoelectric conversion section 12.

Furthermore, in the light shielding wall 50, an end portion 50a (here, an end of the contact electrode wiring 24) on the first semiconductor layer 11 side in the thickness direction of the sensor chip 2 (first semiconductor substrate 10) is joined to the photoelectric conversion section 12 of the first semiconductor layer 11. Specifically, the end portion 50a is connected to the second contact region 18 of the photoelectric conversion section 12. Thus, the light shielding wall 50 divides the interlayer insulating film 60 with the junction surface between the first surface S1 of the first semiconductor layer 11 and the third surface S3 of the first wiring layer 21 as a starting point, and shields light. Therefore, the photodetector 1 is continuously divided by the separation portion 13 and the light shielding wall 50 in the thickness direction.

<Effect>

The photodetector 1 according to the first embodiment includes the light shielding wall 50 provided in the first wiring layer 21 and the second wiring layer 41. Then, the light shielding wall 50 divides the interlayer insulating film 60 into respective portions corresponding to the two adjacent photoelectric conversion sections 12. Thus, light incident on one pixel 3 and reaching the first wiring layer 21 or the second wiring layer 41 is blocked by the light shielding wall 50. In this manner, the light shielding wall 50 suppresses intrusion of light reaching the first wiring layer 21 or the second wiring layer 41 into the adjacent pixels 3 in the lateral direction. Thus, crosstalk between the two adjacent photoelectric conversion sections 12 can be suppressed.

In particular, when the light shielding wall 50 and the separation portion 13 are combined, light does not enter the adjacent pixels 3 from the photoelectric conversion section 12 to the surface 45S of the electrode pad 45.

Furthermore, in the photodetector 1 according to the first embodiment, the light shielding wall 50 is provided in common with a member that supplies the bias voltage VB from the second semiconductor substrate 30 side to the first semiconductor substrate 10 side. Thus, there are fewer design restrictions as compared with a case where the light shielding wall 50 is provided separately from the member that supplies the bias voltage VB.

Furthermore, in the photodetector 1 according to the first embodiment, since the contact electrode wiring 24 is a mesh-like wiring, a contact area with the charge accumulation region 19 functioning as an anode of the photoelectric conversion section 12 is increased. Thus, the supply of the bias voltage VB to the anode can be further strengthened.

Furthermore, in the photodetector 1 according to the first embodiment, the contact electrode wiring 24 is directly joined to the first connection wiring 26. Thus, the first wiring layer 21 is only required to include one layer of the metal M1, and the number of wiring layers can be reduced.

Note that the light shielding wall 50 having a larger dimension in the thickness direction has a larger light shielding effect. In the first embodiment, the light shielding wall 50 includes all of the contact electrode wiring 24, the first connection wiring 26, the second connection wiring 49, and the second via electrode wiring 47. On the other hand, since each of the contact electrode wiring 24, the first connection wiring 26, the second connection wiring 49, and the second via electrode wiring 47 does not pass light in the wavelength band photoelectrically converted by the photoelectric conversion section 12, even in a case where the light shielding wall 50 does not include all of them, a certain degree of light shielding effect is obtained. Thus, the light shielding wall 50 may include only at least one of the contact electrode wiring 24, the first connection wiring 26, the second connection wiring 49, or the second via electrode wiring 47. For example, the light shielding wall 50 may include only the first connection wiring 26 and the second connection wiring 49, or may include only the contact electrode wiring 24. Since the first connection wiring 26 and the second connection wiring 49 are joined to each other, the joined first connection wiring 26 and second connection wiring 49 can gain dimensions in the thickness direction. Furthermore, the contact electrode wiring 24 is joined to the photoelectric conversion section 12. That is, the contact electrode wiring 24 is provided at a position closest to the photoelectric conversion section 12 of the first semiconductor layer 11.

Here, among the portions included in the above-described light shielding wall 50, a portion dividing the interlayer insulating films 61 and 62 (that is, the first interlayer insulating film 22) is referred to as a light shielding wall (fifth light shielding wall) 51 in order to distinguish the portion from other portions of the light shielding wall 50. Similarly, among the portions included in the above-described light shielding wall 50, a portion dividing the interlayer insulating film 65 (that is, the upper interlayer insulating film) is referred to as a light shielding wall (sixth light shielding wall) 52 in order to distinguish the portion from other portions of the light shielding wall 50.

For example, the light shielding wall 50 may include only the light shielding wall 51 penetrating the first interlayer insulating film 22, or may include only the light shielding wall 52 penetrating the interlayer insulating film 65.

Note that the light shielding effect is greater when the light shielding wall 50 is provided at a position closer to the first semiconductor layer 11 in the thickness direction. This is because the light incident on the photoelectric conversion section 12 is more likely to pass through a position closer to the first semiconductor layer 11. Thus, for example, when the light shielding wall 51 and the light shielding wall 52 are compared, both the light shielding wall 51 and the light shielding wall 52 have a light shielding effect, but the light shielding effect of the light shielding wall 51 provided at a position closer to the first semiconductor layer 11 is larger.

Note that, in the above description, a member that is not included in the light shielding wall 50 among the contact electrode wiring 24, the first connection wiring 26, the second connection wiring 49, and the second via electrode wiring 47 is provided in a shape similar to a conventional member, and has a function of supplying the bias voltage VB.

<<First modification of First Embodiment>>

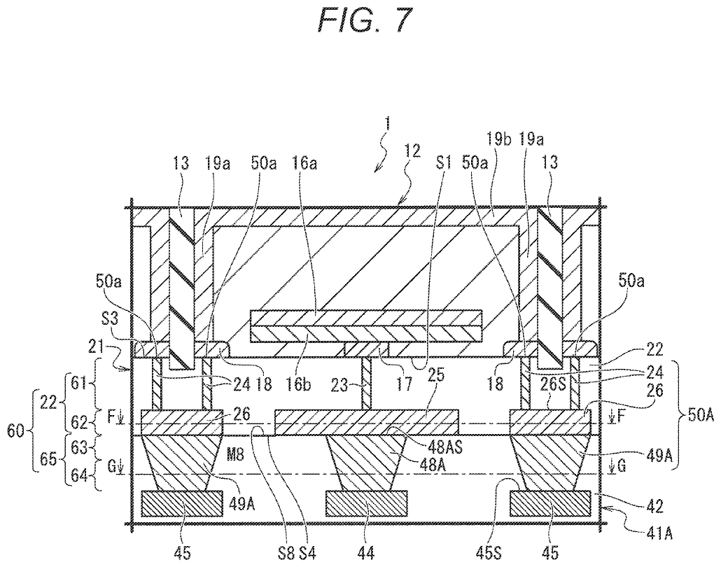

A first modification of the first embodiment of the present technology depicted in FIG. 7 will be described below. The photodetector 1 according to the first modification of the first embodiment is different from the photodetector 1 according to the first embodiment described above in including a second wiring layer 41A and a light shielding wall 50A instead of the second wiring layer 41 and the light shielding wall 50, and other configurations of the photodetector 1 are basically similar to those of the photodetector 1 according to the first embodiment described above. Note that the components already described are denoted by the same reference numerals, and the description thereof will be omitted.

<Configuration of Second Wiring Layer>

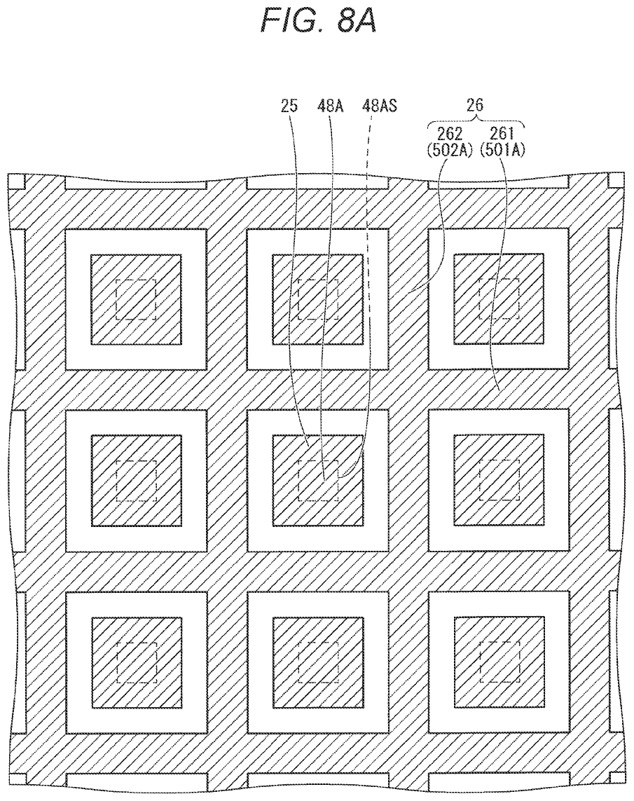

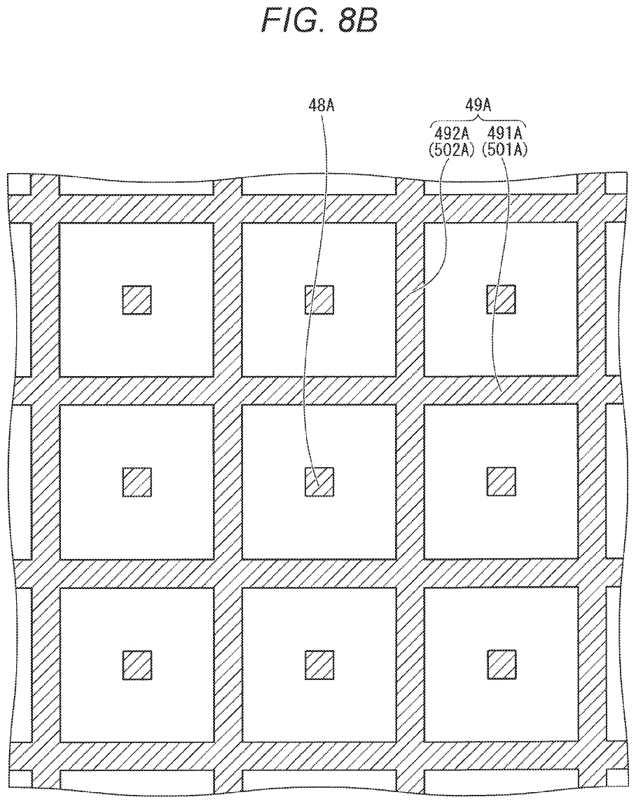

The second wiring layer 41A includes a second connection pad 48A and a second connection wiring 49A which are the metal M8. The second connection pad 48A and the second connection wiring 49A are formed using metal such as copper (Cu), for example. Each of the second connection pad 48A and the second connection wiring 49A is formed by a single damascene method. In the second connection pad 48A, a surface facing the eighth surface S8 is joined to the first connection pad 25, and a surface opposite to the surface facing the eighth surface S8 is joined to the electrode pad 44. As depicted in FIGS. 7 and 8A, the size of a surface 48AS of the second connection pad 48A facing the eighth surface S8 is smaller than a cross section of first connection pad 25.

In the second connection wiring 49A, a surface facing the eighth surface S8 is joined to the first connection wiring 26, and a surface opposite to the surface facing the eighth surface S8 is joined to the electrode pad 45.

<Configuration of Light Shielding Wall>

The light shielding wall 50A includes the contact electrode wiring 24, the first connection wiring 26, and the second connection wiring 49A. Since the second connection wiring 49A is formed by the single damascene method, the light shielding wall 50A does not include the second via electrode wiring 47 of the first embodiment. Hereinafter, the second connection wiring 49A will be described.

(Second Connection Wiring)

As depicted in the cross-sectional view of FIG. 8B, the second connection wiring 49A is a mesh-like wiring. As depicted in FIG. 7, the second connection wiring 49A penetrates a portion of the second interlayer insulating film 42 in the thickness direction, the portion extending and stacked on the X-Y plane between the eighth surface S8 and the surface 45S that is a surface of the electrode pad 45 on the first semiconductor substrate 10 side, that is, the portion corresponding to the combined portion of the interlayer insulating film 63 and the interlayer insulating film 64 in the first embodiment. Here, the interlayer insulating film 63 and the interlayer insulating film 64 are collectively referred to as the interlayer insulating film 65 in order to distinguish them from other interlayer insulating films. Specifically, the second connection wiring 49A divides the interlayer insulating film 65 into respective portions corresponding to the two adjacent photoelectric conversion sections 12. That is, the second connection wiring 49A is a light shielding wall (third light shielding wall) that divides the interlayer insulating film 65. Furthermore, the second connection wiring 49A is provided between the adjacent reading electrodes, that is, between the adjacent second connection pads 48A.

As depicted in FIG. 8B, the second connection wiring 49A includes a first portion 491A extending along both the thickness direction and the row direction, and a second portion 492A extending along both the thickness direction and the column direction. The first portion 491A divides the interlayer insulating film 65 into respective portions corresponding to the two photoelectric conversion sections 12 adjacent to each other in the column direction. The second portion 492A divides the interlayer insulating film 65 into respective portions corresponding to the two photoelectric conversion sections 12 adjacent to each other in the row direction. Furthermore, the second connection wiring 49A is provided so as to surround one second connection pad 48A by the first portion 491A and the second portion 492A. The second connection wiring 49A has been described above.

Since the contact electrode wiring 24, the first connection wiring 26, and the second connection wiring 49A as described above are overlapped and joined in this order, the light shielding wall 50A penetrates the interlayer insulating films 61, 62, and 65 in the thickness direction, that is, penetrates the interlayer insulating film 60 in the thickness direction. Specifically, the light shielding wall 50A divides the interlayer insulating film 60 into respective portions corresponding to the two adjacent photoelectric conversion sections 12.

Furthermore, the light shielding wall 50A includes a first portion 501A extending along both the thickness direction and the row direction, and a second portion 502A extending along both the thickness direction and the column direction. Since the light shielding wall 50A includes the contact electrode wiring 24, the first connection wiring 26, and the second connection wiring 49A, the first portion 501A includes the first portions 241, 261, and 491A. Similarly, the second portion 502A includes the second portions 242, 262, and 492A.

<Effect>

Even in the photodetector 1 according to the first modification of the first embodiment, effects similar to those of the photodetector 1 according to the first embodiment described above can be obtained.

Furthermore, in the photodetector 1 according to the first modification of the first embodiment, the process of forming the second via electrode 46 and the second via electrode wiring 47 of the first embodiment can be reduced.

<<Second Modification of First Embodiment>>

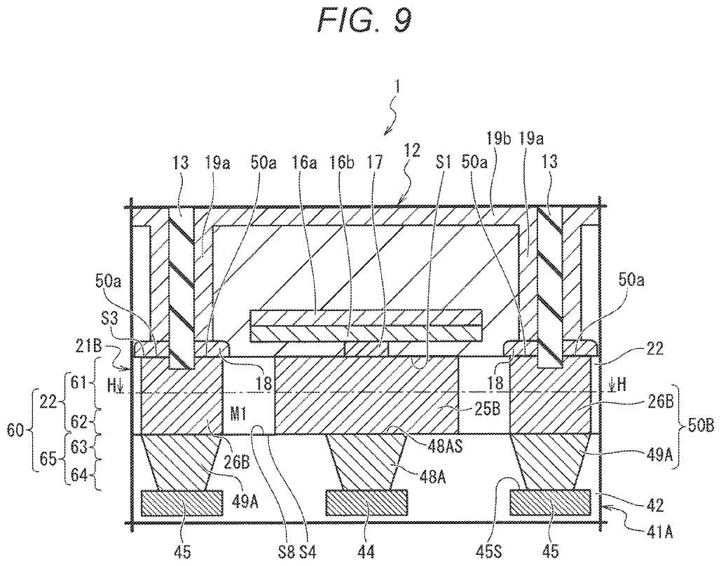

A second modification of the first embodiment of the present technology depicted in FIG. 9 will be described below. The photodetector 1 according to the second modification of the first embodiment is different from the photodetector 1 according to the first embodiment described above in including a first wiring layer 21B, the second wiring layer 41A, and a light shielding wall 50B instead of the first wiring layer 21, the second wiring layer 41, and the light shielding wall 50, and other configurations of the configuration of the photodetector 1 are basically similar to the configuration of the photodetector 1 of the first embodiment described above. Note that the components already described are denoted by the same reference numerals, and the description thereof will be omitted.

<Configuration of First Wiring Layer>

The first wiring layer 21B includes a first connection pad that is the metal M1 and a first connection wiring 26B. The first connection pad 25B and the first connection wiring 26B are formed using metal such as copper (Cu), for example. Each of the first connection pad 25B and the first connection wiring 26B is formed by a single damascene method. In the first connection pad a surface facing the fourth surface S4 is joined to the second connection pad 48A, and a surface opposite to the surface facing the fourth surface S4 is joined to the photoelectric conversion section 12 of the first semiconductor layer 11, specifically, the first contact region 17 of the photoelectric conversion section 12. In the first connection wiring 26B, a surface facing the fourth surface S4 is joined to the second connection wiring 49A, and a surface opposite to the surface facing the fourth surface S4 is joined to the photoelectric conversion section 12 of the first semiconductor layer 11, specifically, the second contact region 18 of the photoelectric conversion section 12. Note that the second wiring layer 41A has already been described in the first modification of the first embodiment, and thus the description thereof will be omitted here.

<Configuration of Light Shielding Wall>

The light shielding wall 50B includes a first connection wiring 26B and a second connection wiring 49A. Hereinafter, the first connection wiring 26B will be described. Since the first connection wiring 26B is formed by the single damascene method, the light shielding wall 50B does not include the contact electrode wiring 24 of the first embodiment. Note that the second connection wiring 49A has already been described in the first modification of the first embodiment, and thus the description thereof will be omitted here.

(First Connection Wiring)

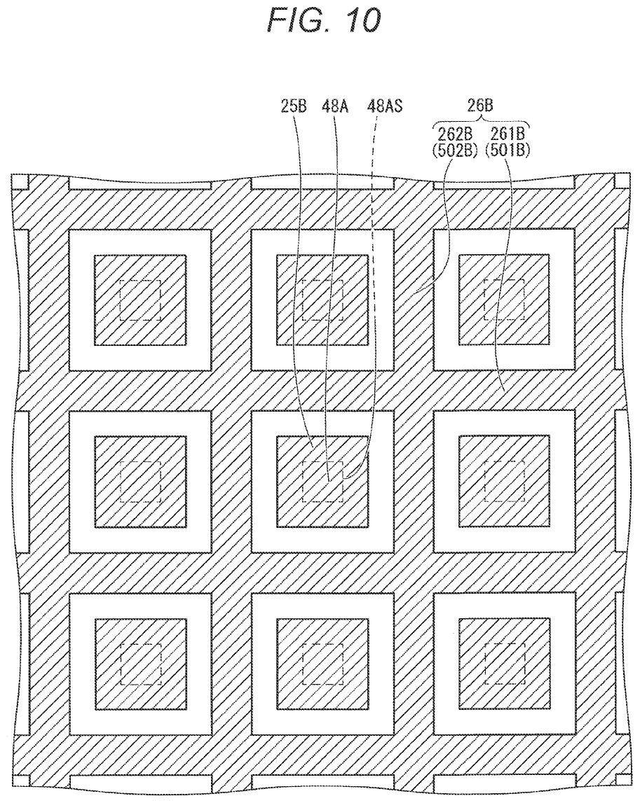

As depicted in the cross-sectional view of FIG. 10, the first connection wiring 26B is a mesh-like wiring. As depicted in FIG. 9, the first connection wiring 26B penetrates a portion of the first interlayer insulating film 22 in the thickness direction, the portion extending and stacked on an X-Y plane between the third surface S3 and the fourth surface S4, that is, the portion corresponding to the combined portion of the interlayer insulating film 61 and the interlayer insulating film 62 in the first embodiment. Specifically, the first connection wiring 26B divides the first interlayer insulating film 22 into respective portions corresponding to the two adjacent photoelectric conversion sections 12. That is, the first connection wiring 26B is a light shielding wall (second light shielding wall) that divides the first interlayer insulating film 22. The first interlayer insulating film 22 is an interlayer insulating film included in the first wiring layer 21. Furthermore, the first connection wiring 26B is provided between the adjacent reading electrodes, that is, between the adjacent first connection pads 25B.

As depicted in FIG. 10, the first connection wiring 26B includes a first portion 261B extending along both the thickness direction and the row direction, and a second portion 262B extending along both the thickness direction and the column direction. The first portion 261B divides the interlayer insulating film 62 into respective portions corresponding to the two photoelectric conversion sections 12 adjacent to each other in the column direction. The second portion 262B divides the interlayer insulating film 62 into respective portions corresponding to the two photoelectric conversion sections 12 adjacent to each other in the row direction. Furthermore, the first connection wiring 26B is provided so as to surround one first connection pad 25B by the first portion 261B and the second portion 262B. The first connection wiring 26B has been described above.

Since the first connection wiring 26B and the second connection wiring 49A as described above are overlapped and joined, the light shielding wall 50B penetrates the first interlayer insulating films 22 and 65 in the thickness direction, that is, penetrates the interlayer insulating film 60 in the thickness direction. Specifically, the light shielding wall 50B divides the interlayer insulating film 60 into respective portions corresponding to the two adjacent photoelectric conversion sections 12.

Furthermore, the light shielding wall 50B includes a first portion 501B extending along both the thickness direction and the row direction, and a second portion 502B extending along both the thickness direction and the column direction. Since the light shielding wall 50B includes the first connection wiring 26B and the second connection wiring 49A, the first portion 501B includes the first portions 261B and 491A. Similarly, the second portion 502B includes the second portions 262B and 492A.

<Effect>

Even in the photodetector 1 according to the second modification of the first embodiment, effects similar to those of the photodetector 1 according to the first embodiment described above can be obtained.

Furthermore, in the photodetector 1 according to the second modification of the first embodiment, it is possible to reduce the number of steps of forming the contact electrode 23, the contact electrode wiring 24, the second via electrode 46 of the first embodiment, and the second via electrode wiring 47.

Note that, in the second modification of the first embodiment, the second connection pad 48 and the second connection wiring 49 and the second via electrode 46 and the second via electrode wiring 47 may be included instead of the second connection pad 48A and the second connection wiring 49A.

<<Third Modification of First Embodiment>>

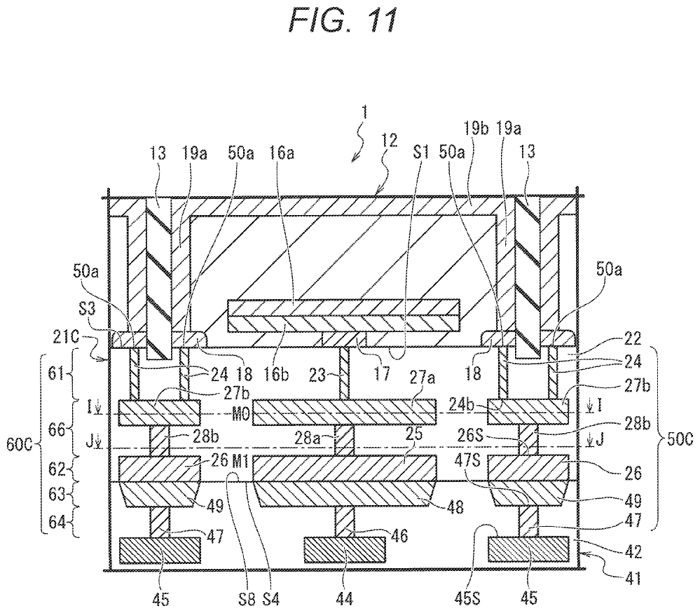

A third modification of the first embodiment of the present technology depicted in FIG. 11 will be described below. The photodetector 1 according to the third modification of the first embodiment is different from the photodetector 1 according to the first embodiment described above in including a first wiring layer 21C and a light shielding wall 50C instead of the first wiring layer 21 and the light shielding wall 50, and other configurations of the photodetector 1 are basically similar to those of the photodetector 1 of the first embodiment described above. Note that the components already described are denoted by the same reference numerals, and the description thereof will be omitted.

<Configuration of First Wiring Layer>

The first wiring layer 21C includes, in addition to the components of the first wiring layer 21 of the first embodiment, a reflective pad 27a and a first wiring 27b that are metal M0, and a first via electrode 28a and a first via electrode wiring 28b that connect the metal M0 and the metal M1. The reflective pad 27a and the first wiring 27b as well as the first via electrode 28a and the first via electrode wiring 28b are formed using metal such as copper (Cu), for example. The reflective pad 27a functions as a reflector that reflects light incident from the light incident surface side.

The first contact region 17 is electrically connected to the electrode pad 44 via the contact electrode 23, the reflective pad 27a, the first via electrode 28a, the first connection pad 25, the second connection pad 48, and the second via electrode 46 in this order.

Furthermore, the second contact region 18 is electrically connected to the electrode pad 45 via the contact electrode wiring 24, the first wiring 27b, the first via electrode wiring 28b, the first connection wiring 26, the second connection wiring 49, and the second via electrode wiring 47 in this order.

<Configuration of Light Shielding Wall>

The light shielding wall 50C includes the contact electrode wiring 24, the first wiring 27b, the first via electrode wiring 28b, the first connection wiring 26, the second connection wiring 49, and the second via electrode wiring 47. Hereinafter, the first wiring 27b and the first via electrode wiring 28b will be described.

(Configurations of First Wiring and First Via Electrode Wiring)

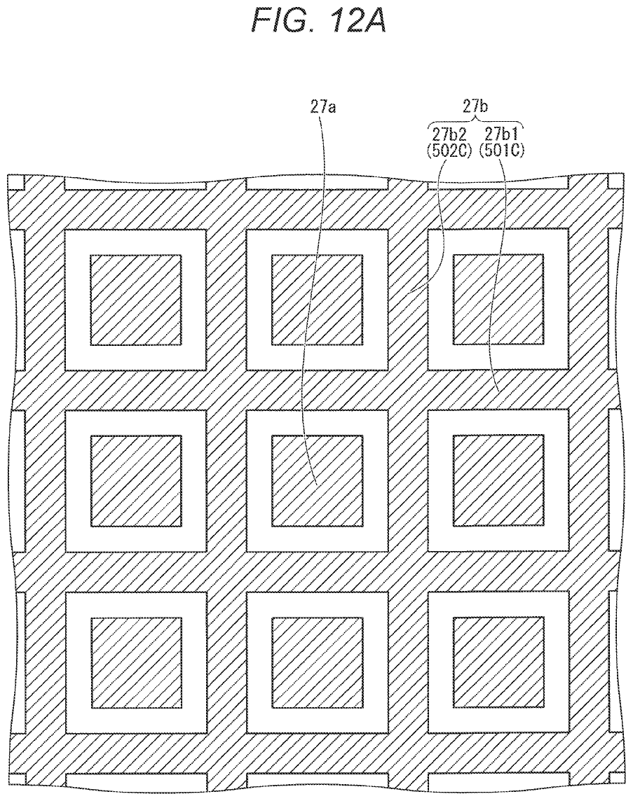

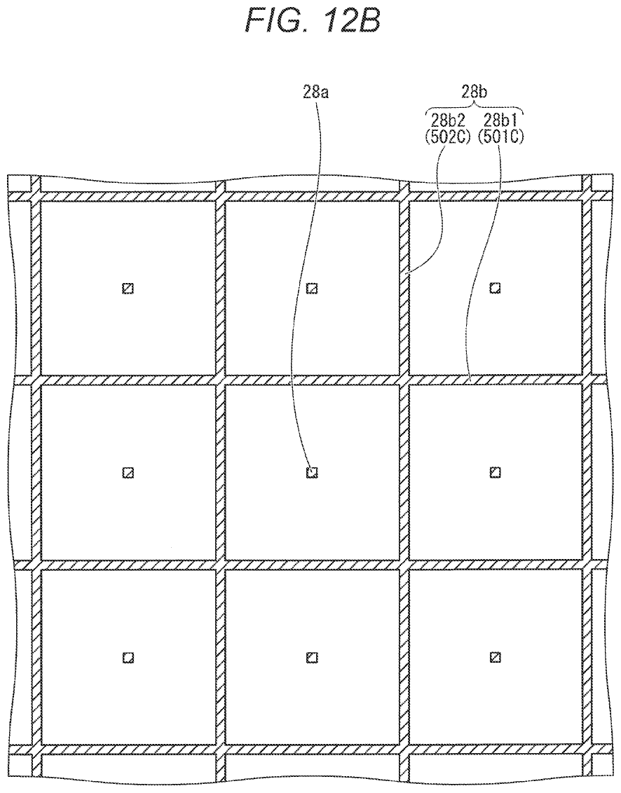

As depicted in the cross-sectional view of FIG. 12A, the first wiring 27b is a mesh-like wiring. As depicted in the cross-sectional view of FIG. 12B, the first via electrode wiring 28b is a mesh-like wiring. Specifically, the first wiring 27b and the first via electrode wiring 28b are provided by forming grooves in the first interlayer insulating film 22 and filling the groove with metal. Furthermore, the first wiring 27b is provided between the adjacent reading electrodes, that is, between the adjacent reflective pads 27a. Then, the first via electrode wiring 28b is provided between the adjacent reading electrodes, that is, between the adjacent first via electrodes 28a. As depicted in FIG. 11, the first wiring 27b and the first via electrode wiring 28b penetrate a portion of the first interlayer insulating film 22 in the thickness direction, the portion extending and stacked on an X-Y plane between the end portion 24b on the opposite side of the end portion 50a of the contact electrode wiring 24 and the surface 26S that is a surface of the first connection wiring 26 on the first semiconductor layer 11 side. Here, the interlayer insulating film divided by the first wiring 27b and the first via electrode wiring 28b is referred to as an interlayer insulating film 66 in order to distinguish the interlayer insulating film from other interlayer insulating films. Specifically, the first wiring 27b and the first via electrode wiring 28b divide the interlayer insulating film 66 into respective portions corresponding to the two adjacent photoelectric conversion sections 12. That is, the first wiring 27b and the first via electrode wiring 28b are light shielding walls (seventh light shielding walls) that divide the interlayer insulating film 66. The interlayer insulating film 66 is a part of the interlayer insulating film included in the first wiring layer 21.

As depicted in FIG. 12A, the first wiring 27b includes a first portion 27b1 extending along both the thickness direction and the row direction, and a second portion 27b2 extending along both the thickness direction and the column direction. As depicted in FIG. 12B, the first via electrode wiring 28b has a first portion 28b1 extending along both the thickness direction and the row direction, and a second portion 28b2 extending along both the thickness direction and the column direction. The first portions 27b1 and 28b1 divide the interlayer insulating film 66 into respective portions corresponding to the two photoelectric conversion sections 12 adjacent to each other in the column direction. The second portions 27b2 and 28b2 divide the interlayer insulating film 66 into respective portions corresponding to the two photoelectric conversion sections 12 adjacent to each other in the row direction.

Furthermore, the first wiring 27b is provided so as to surround one reflective pad 27a by the first portion 27b1 and the second portion 27b2. Then, the first via electrode wiring 28b is provided so as to surround one first via electrode 28a by the first portion 28b1 and the second portion 28b2.

The first wiring 27b and the first via electrode wiring 28b have been described above.

The light shielding wall 50C penetrates the interlayer insulating films 61, 66, 62, 63, and 64 in the thickness direction. Here, the interlayer insulating films 61, 66, 62, 63, and 64 are collectively referred to as an interlayer insulating film 60C. Specifically, the light shielding wall 50C divides the interlayer insulating film 60C into respective portions corresponding to the two adjacent photoelectric conversion sections 12.

Furthermore, the light shielding wall 50C includes a first portion 501C extending along both the thickness direction and the row direction, and a second portion 502C extending along both the thickness direction and the column direction. The first portion 501C includes the first portions 241, 27b1, 28b1, 261, 491, and 471. Similarly, the second portion 502C includes the second portions 242, 27b2, 28b2, 262, 492, and 472.

Furthermore, since the first wiring 27b and the first via electrode wiring 28b are formed using metal as described above, light in the wavelength band that can be photoelectrically converted by the photoelectric conversion section 12 does not pass therethrough.

<Effect>

Even in the photodetector 1 according to the third modification of the first embodiment, effects similar to those of the photodetector 1 according to the first embodiment described above can be obtained.

Furthermore, in the photodetector 1 according to the third modification of the first embodiment, a thickness of the light shielding wall 50C is larger than that of the light shielding wall 50 of the first embodiment by a size corresponding to thicknesses of the first wiring 27b and the first via electrode wiring 28b (a thickness of the interlayer insulating film 66). Accordingly, a dimension of the light shielding wall 50C in the thickness direction of the sensor chip 2 is also larger than that of the light shielding wall 50 of the first embodiment. When the dimension of the light shielding wall 50C in the thickness direction of the sensor chip 2 increases, the range shielded by the light shielding wall 50C is widened, and thus the light shielding effect is further increased.

<<Fourth Modification of First Embodiment>>

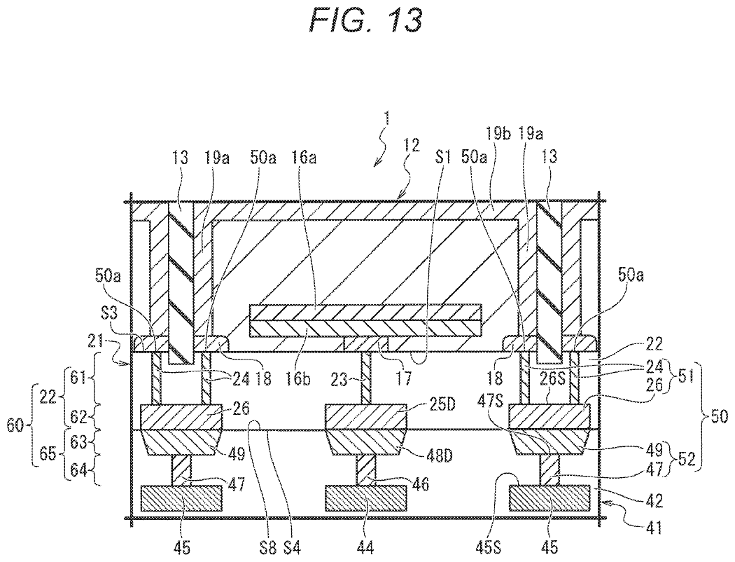

A fourth modification of the first embodiment of the present technology depicted in FIG. 13 will be described below. The photodetector 1 according to the fourth modification of the first embodiment is different from the photodetector 1 according to the first embodiment described above in including a first connection pad 25D and a second connection pad 48D instead of the first connection pad 25 and the second connection pad 48, and other configurations of the photodetector 1 are basically similar to those of the photodetector 1 according to the first embodiment described above. Note that the components already described are denoted by the same reference numerals, and the description thereof will be omitted.

(Configurations of First Connection Pad and Second Connection Pad)

Dimensions of the first connection pad 25D in the X direction and the Y direction are the same as the dimensions of the first connection wiring 26 in the X direction. Dimensions of the second connection pad 48D in the X direction and the Y direction are the same as the dimensions of the second connection wiring 49 in the X direction. In the fourth modification of the first embodiment, the first connection pad 25D and the second connection pad 48D do not have a function as a reflector.

<Effect>

Even in the photodetector 1 according to the fourth modification of the first embodiment, effects similar to those of the photodetector 1 according to the first embodiment described above can be obtained.

### Second Embodiment

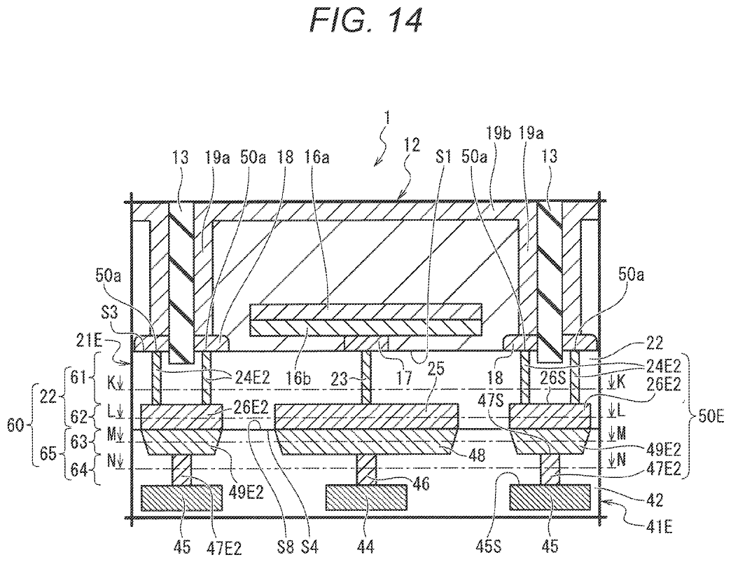

A second embodiment of the present technology depicted in FIG. 14 will be described below. The light shielding wall 50 according to the first embodiment described above includes both the first portion 501 and the second portion 502, whereas a light shielding layer according to the first embodiment does not include the first portion 501 and includes only the second portion 502. That is, the light shielding wall in the second embodiment divides the interlayer insulating film into respective portions corresponding to the photoelectric conversion sections 12 only for two photoelectric conversion sections 12 adjacent to each other in the row direction, and does not divide the interlayer insulating film into respective portions corresponding to the photoelectric conversion sections 12 for two photoelectric conversion sections 12 adjacent to each other in the column direction. That is, the light shielding wall 50 divides the reading electrodes adjacent to each other in the row direction by the second portion 502.

The second embodiment is different from the first embodiment described above in including a first wiring layer 21E, a second wiring layer 41E, and a light shielding wall 50E instead of the first wiring layer 21, the second wiring layer 41, and the light shielding wall 50, and the other configurations of the photodetector 1 are basically similar to those of the photodetector 1 of the first embodiment described above. Note that the components already described are denoted by the same reference numerals, and the description thereof will be omitted.

<Configuration of First Wiring Layer>

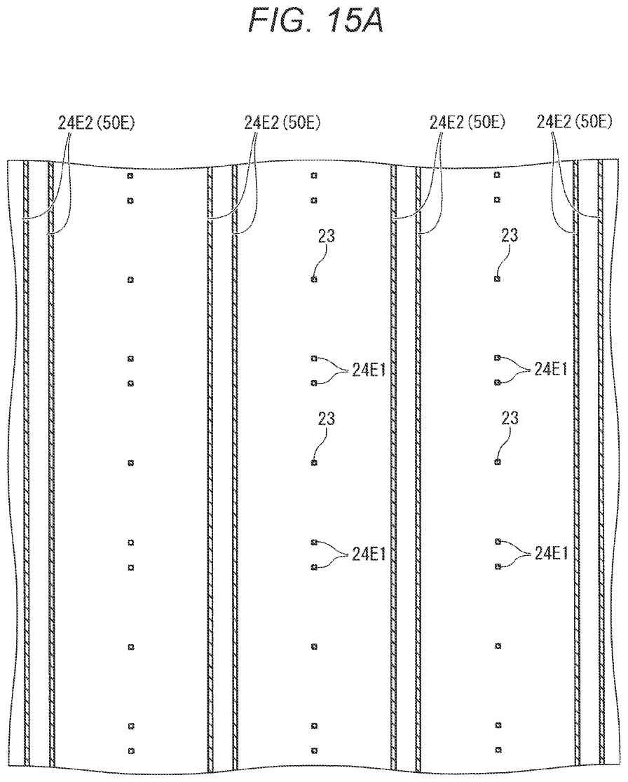

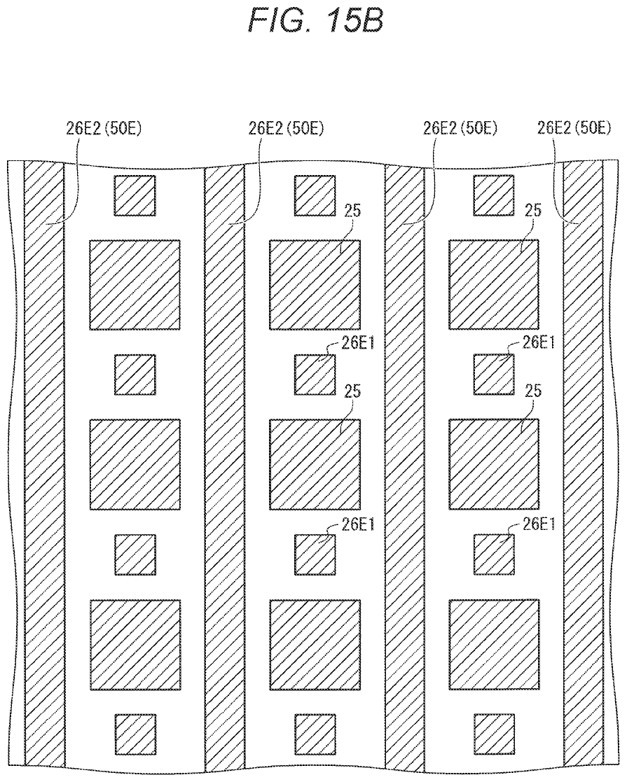

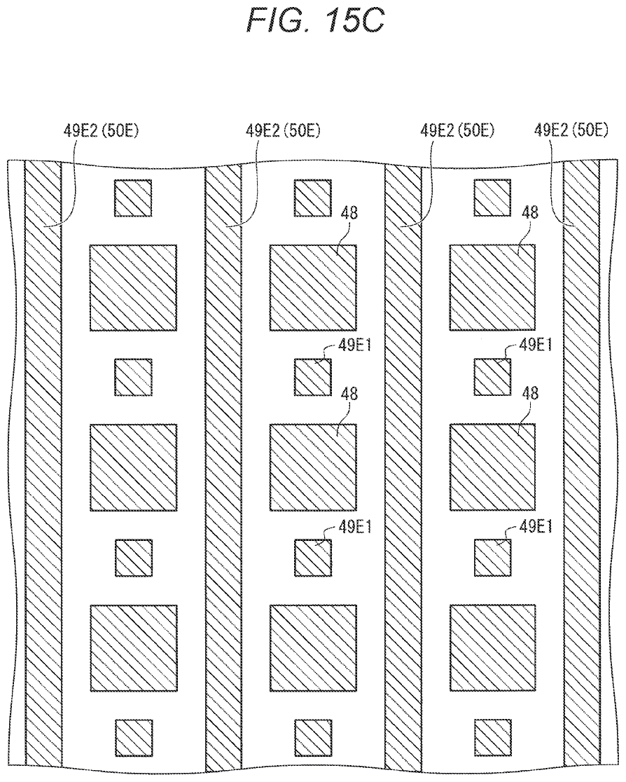

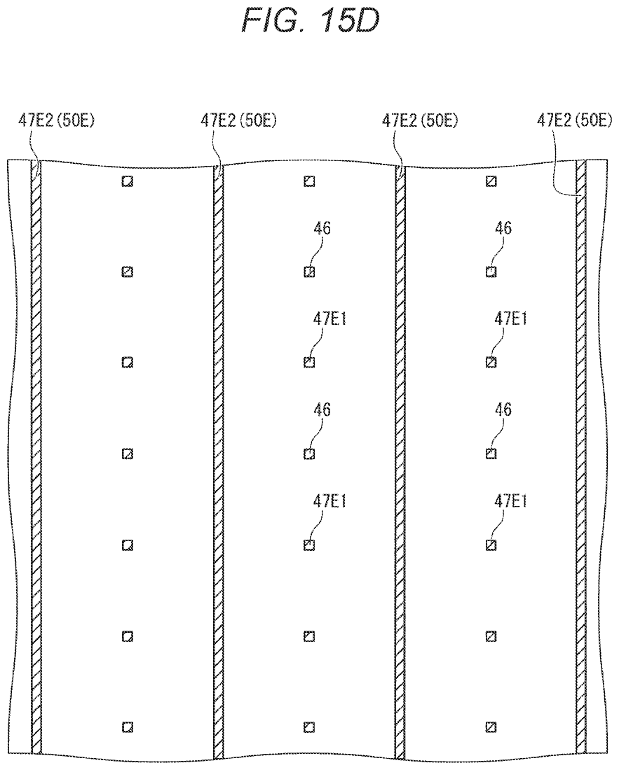

As depicted in FIGS. 14 and 15A, the first wiring layer 21E includes contact electrodes 24E1 and contact electrode wirings 24E2 instead of the contact electrode wiring 24 of the first embodiment. Moreover, as depicted in FIGS. 14 and 15B, the first wiring layer 21E includes a first connection pad 26E1 and first connection wirings 26E2 instead of the first connection wiring 26 of the first embodiment.

<Configuration of Second Wiring Layer>

As depicted in FIGS. 14 and 15C, the second wiring layer 41E includes a second connection pad 49E1 and a second connection wiring 49E2 instead of the second connection wiring 49 of the first embodiment. Moreover, as depicted in FIGS. 14 and 15D, the second wiring layer 41E includes a second via electrode 47E1 and a second via electrode wiring 47E2 instead of the second via electrode wiring 47 of the first embodiment.

<Configuration of Light Shielding Wall>

The light shielding wall 50E includes the contact electrode wirings 24E2, the first connection wirings 26E2, the second connection wiring 49E2, and the second via electrode wiring 47E2. Each component will be described below.

(Contact Electrode Wiring)

As depicted in the cross-sectional view of FIG. 15A, the contact electrode wirings 24E2 are linear wirings formed by extending conventional through hole electrodes along the column direction. On the other hand, the contact electrodes 24E1 are conventional through hole electrodes. As depicted in FIG. 14, the contact electrode wirings 24E2 penetrate a portion of the first interlayer insulating film 22 in the thickness direction, the portion extending and stacked on the X-Y plane between the third surface S3 and the surface 26S that is a surface of the first connection wiring 26E2 on the first semiconductor layer 11 side, that is, the interlayer insulating film 61. Specifically, the contact electrode wirings 24E2 divide the interlayer insulating film 61 into respective portions corresponding to the two photoelectric conversion sections 12 adjacent to each other in the row direction. That is, the contact electrode wirings 24E2 are light shielding walls (first light shielding walls) that divides the interlayer insulating film 61. Note that, in the second embodiment, the column direction is a direction along a scanning direction indicated by the arrow S in FIG. 2. Furthermore, the contact electrode wirings 24E2 are disposed between the reading electrodes adjacent to each other in the row direction, that is, the contact electrodes 23 adjacent to each other in the row direction, thereby dividing the contact electrodes 23 adjacent to each other in the row direction.

(First Connection Wiring)

As depicted in the cross-sectional view of FIG. 15B, the first connection wirings 26E2 are linear wirings obtained by extending a pad electrode having a conventional quadrangular shape along the column direction. On the other hand, the first connection pad 26E1 is a conventional quadrangular pad electrode. As depicted in FIG. 14, the first connection wirings 26E2 penetrate a portion of the first interlayer insulating film 22 in the thickness direction, the portion extending and stacked on the X-Y plane between the surface 26S and the fourth surface S4, that is, the interlayer insulating film 62. Specifically, the first connection wirings 26E2 divide the interlayer insulating film 62 into respective portions corresponding to the two photoelectric conversion sections 12 adjacent to each other in the row direction. That is, the first connection wirings 26E2 are light shielding walls (second light shielding walls) that divides the interlayer insulating film 62. Furthermore, the first connection wirings 26E2 are disposed between the reading electrodes adjacent to each other in the row direction, that is, the first connection pads 25 adjacent to each other in the row direction, thereby dividing the first connection pads 25 adjacent to each other in the row direction.

(Second Connection Wiring)

As depicted in the cross-sectional view of FIG. 15C, the second connection wiring 49E2 is a linear wiring obtained by extending a pad electrode having a conventional quadrangular shape along the column direction. On the other hand, the second connection pad 49E1 is a conventional square pad electrode. As depicted in FIG. 14, the second connection wiring 49E2 penetrates a portion of the second interlayer insulating film 42 in the thickness direction, the portion extending and stacked on the X-Y plane between the eighth surface S8 and the surface 47S that is a surface of the second via electrode wiring 47E2 on the first semiconductor substrate 10 side, that is, the interlayer insulating film 63. Specifically, the second connection wiring 49E2 divides the interlayer insulating film 63 into respective portions corresponding to the two photoelectric conversion sections 12 adjacent to each other in the row direction. That is, the second connection wiring 49E2 is a light shielding wall (third light shielding wall) that divides the interlayer insulating film 63. Furthermore, the second connection wiring 49E2 is disposed between the reading electrodes adjacent to each other in the row direction, that is, the second connection pads 48 adjacent to each other in the row direction, thereby dividing the second connection pads 48 adjacent to each other in the row direction.

(Second Via Electrode Wiring)

As depicted in the cross-sectional view of FIG. 15D, the second via electrode wiring 47E2 is a linear wiring formed by extending a conventional through hole electrode along the column direction. On the other hand, the second via electrode 47E1 is a conventional through hole electrode. As depicted in FIG. 14, the second via electrode wiring 47E2 penetrates a portion of the second interlayer insulating film 42 in the thickness direction, the portion extending and stacked on the X-Y plane between the surface 47S and the surface 45S that is a surface of the electrode pad 45 on the first semiconductor substrate 10 side, that is, the interlayer insulating film 64. Specifically, the second via electrode wiring 47E2 divides the interlayer insulating film 64 into respective portions corresponding to the two photoelectric conversion sections 12 adjacent to each other in the row direction. That is, the second via electrode wiring 47E2 is a light shielding wall (fourth light shielding wall) that divides the interlayer insulating film 64. The second via electrode wiring 47E2 has been described above. Furthermore, the second via electrode wiring 47E2 is disposed between the reading electrodes adjacent to each other in the row direction, that is, the second via electrodes 46 adjacent to each other in the row direction, thereby dividing the second via electrodes 46 adjacent to each other in the row direction.

Since the contact electrode wirings 24E2, the first connection wirings 26E2, the second connection wiring 49E2, and the second via electrode wiring 47E2 as described above are overlapped and joined in this order, the light shielding wall penetrates from the interlayer insulating film 61 to the interlayer insulating film 64, that is, the interlayer insulating film 60 in the thickness direction. The light shielding wall 50E corresponds to the second portion 502 included in the light shielding wall 50 according to the first embodiment. That is, the light shielding wall 50E is provided only along the column direction and penetrates the interlayer insulating film 60 in the thickness direction.

As described above, the light shielding wall 50E divides the interlayer insulating film 60 into respective portions corresponding to the two photoelectric conversion sections 12 adjacent to each other in the row direction. On the other hand, the light shielding wall 50E does not divide the interlayer insulating film 60 into respective portions corresponding to the two photoelectric conversion sections 12 adjacent to each other in the column direction. That is, the light shielding wall 50E shields only crosstalk in the row direction.

<Effect>

Even in the photodetector 1 according to the second embodiment, effects similar to those of the photodetector 1 according to the first embodiment described above can be obtained.

Furthermore, in the photodetector 1 according to the second embodiment, the light shielding wall 50E suppresses crosstalk in the row direction by being provided along the column direction. For example, in a case where the photodetector 1 is mounted on a vehicle, or the like, it is sufficient if the position in a left-right direction (row direction) of a detection object can be grasped accurately, and the position in the up-down direction (column direction) of the detection object may not be as important as the left-right direction. In such a case, it is sufficient if crosstalk can be prevented only in a more important direction.

Note that the light shielding wall 50E may be configured to suppress crosstalk in the column direction by being provided along the row direction depending on the detection object.

Furthermore, the photodetector 1 may not include the contact electrodes 24E1, the first connection pad 26E1, the second connection pad 49E1, and the second via electrode 47E1 described above.

<<First modification of Second Embodiment>>

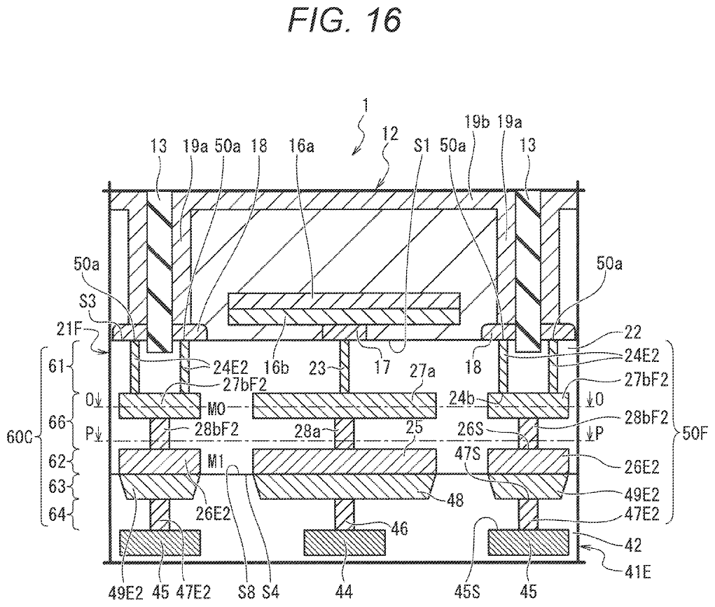

A first modification of the second embodiment of the present technology depicted in FIG. 16 will be described below. In the first modification of the second embodiment, the technology according to the above-described second embodiment is applied to the third modification of the first embodiment. The first modification of the second embodiment is different from the second embodiment in including a first wiring layer 21F and a light shielding wall 50F instead of the first wiring layer 21E and the light shielding wall 50E, and other configurations of the photodetector 1 are basically similar to those of the photodetector 1 of the second embodiment described above. Note that the components already described are denoted by the same reference numerals, and the description thereof will be omitted.

<Configuration of First Wiring Layer>

The first wiring layer 21F includes, in addition to the components of the first wiring layer 21E of the second embodiment described above, the reflective pad 27a that is the metal M0, a first electrode pad 27bF1, and a first wiring 27bF2. Moreover, the first wiring layer 21F includes the first via electrode 28a connecting the metal M0 and the metal M1, a first via electrode 28bF1, and a first via electrode wiring 28bF2.

<Configuration of Light Shielding Wall>

The light shielding wall 50F includes the contact electrode wirings 24E2, the first wiring 27bF2, the first via electrode wiring 28bF2, the first connection wirings 26E2, the second connection wiring 49E2, and the second via electrode wiring 47E2 connected in this order. Hereinafter, the first wiring 27bF2 and the first via electrode wiring 28bF2 will be described.

(Configurations of First Wiring and First Via Electrode Wiring)

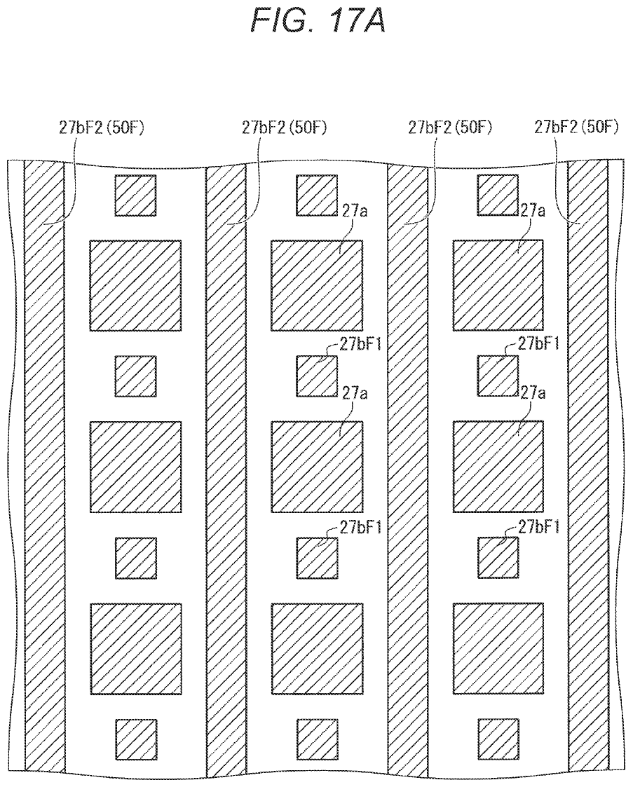

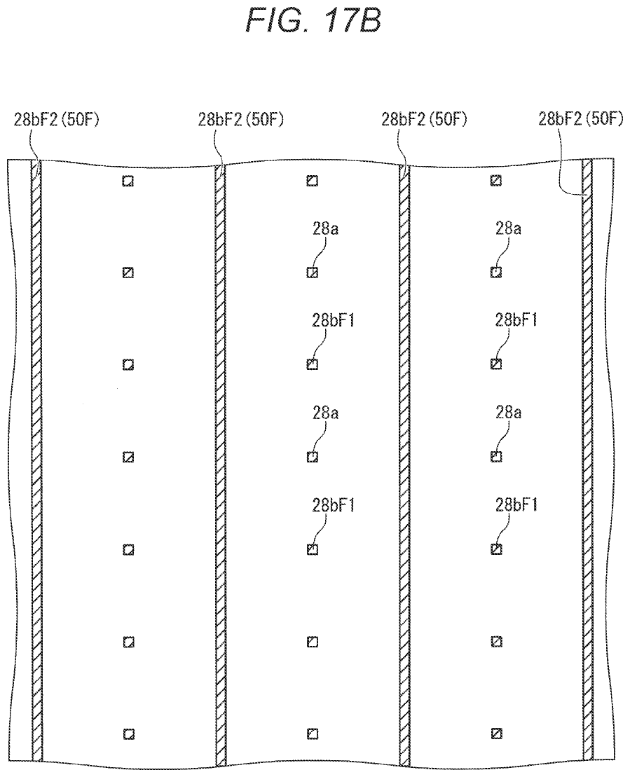

As depicted in the cross-sectional view of FIG. 17A, the first wiring 27bF2 is a linear wiring. On the other hand, the first electrode pad 27bF1 is a conventional square pad electrode. As depicted in the cross-sectional view of FIG. 17B, the first via electrode wiring 28bF2 is a linear wiring. On the other hand, the first via electrode 28bF1 is a conventional through hole electrode. As depicted in FIG. 16, the first wiring 27bF2 and the first via electrode wiring 28bF2 penetrate a portion of the first interlayer insulating film 22 in the thickness direction, the portion extending and stacked on an X-Y plane between the end portion 24b on the opposite side of the end portion 50a of the contact electrode wiring 24E2 and the surface 26S that is a surface of the first connection wiring 26 on the first semiconductor layer 11 side, that is, the interlayer insulating film 66. Specifically, the first wiring 27bF2 and the first via electrode wiring 28bF2 divide the interlayer insulating film 66 into respective portions corresponding to the two photoelectric conversion sections 12 adjacent to each other in the row direction. That is, the first wiring 27bF2 and the first via electrode wiring 28bF2 are light shielding walls (seventh light shielding walls) that divide the interlayer insulating film 66. Further, the first wiring 27bF2 is disposed between the reading electrodes adjacent to each other in the row direction, that is, the reflective pads 27a adjacent to each other in the row direction, thereby dividing the reflective pads 27a adjacent to each other in the row direction. Furthermore, the first via electrode wiring 28bF2 is disposed between the reading electrodes adjacent to each other in the row direction, that is, the first via electrodes 28a adjacent to each other in the row direction, thereby dividing the first via electrodes 28a adjacent to each other in the row direction. The first wiring 27bF2 and the first via electrode wiring 28bF2 have been described above.

Since the contact electrode wirings 24E2, the first wiring 27bF2, the first via electrode wiring 28bF2, the first connection wirings 26E2, the second connection wiring 49E2, and the second via electrode wiring 47E2 as described above are overlapped and joined in this order, the light shielding wall penetrates 61, 66, 62, 63, and 64, that is, the interlayer insulating film 60C in the thickness direction. The light shielding wall 50F corresponds to the second portion 502C included in the light shielding wall 50C according to the third modification of the first embodiment. That is, the light shielding wall 50F penetrates the interlayer insulating film 60C in the thickness direction along the column direction.

As described above, the light shielding wall 50F divides the interlayer insulating film 60C into respective portions corresponding to the two photoelectric conversion sections 12 adjacent to each other in the row direction. On the other hand, the light shielding wall 50F does not divide the interlayer insulating film 60C into respective portions corresponding to the two photoelectric conversion sections 12 adjacent to each other in the column direction. That is, the light shielding wall shields only crosstalk in the row direction.

<Effect>

Even in the photodetector 1 according to the first modification of the second embodiment, effects similar to those of the photodetector 1 according to the second embodiment described above can be obtained.

Note that the photodetector 1 may not include the contact electrodes 24E1, the first electrode pad 27bF1, the first via electrode 28bF1, the first connection pad 26E1, the second connection pad 49E1, and the second via electrode 47E1 described above.

<<Second Modification of Second Embodiment>>

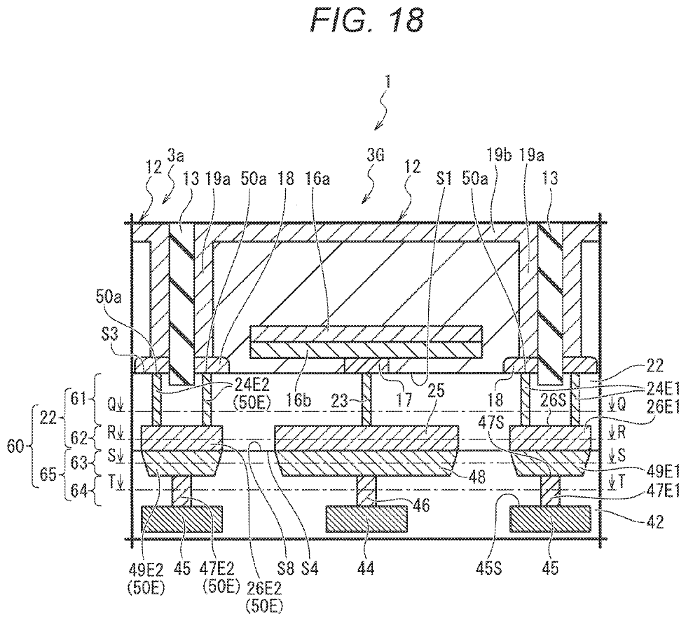

A second modification of the second embodiment of the present technology depicted in FIG. 18 will be described below. In the second modification of the second embodiment, the technology according to the second embodiment is applied to a part of the plurality of pixels 3 included in the first embodiment. Here, a case where the technology according to the second embodiment is applied to a pixel 3G among the plurality of pixels 3 included in the first embodiment will be described. Furthermore, here, the pixels 3 other than the pixel 3G have the same configuration as the pixels 3 included in the above-described first embodiment. Here, a pixel 3a will be described as an example of such pixels 3. The components already described are denoted by the same reference numerals, and the description thereof will be omitted.

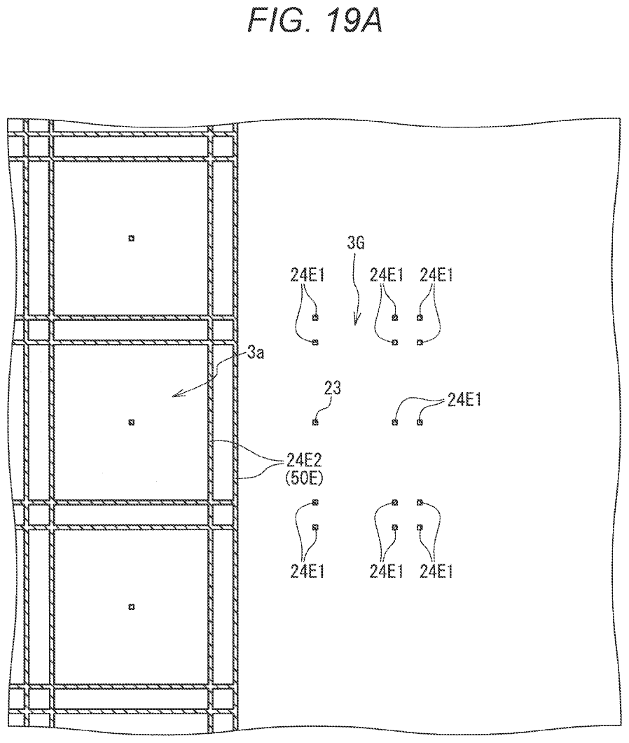

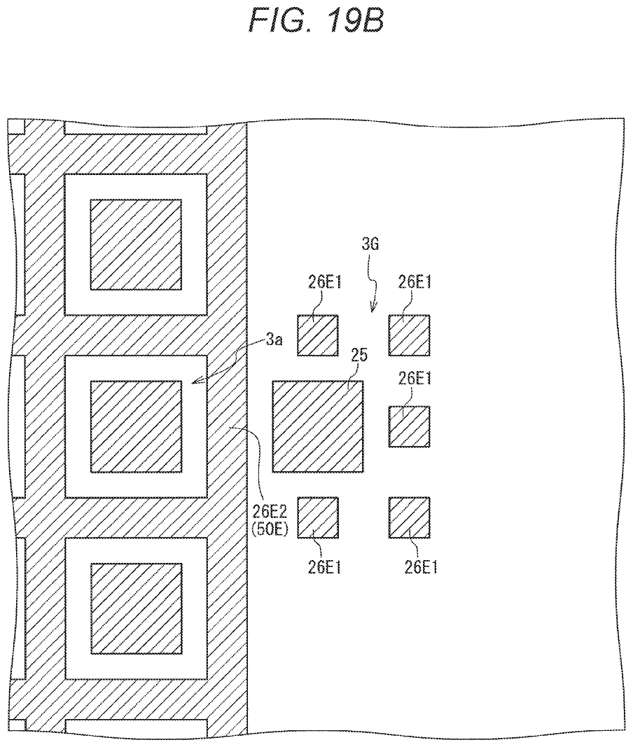

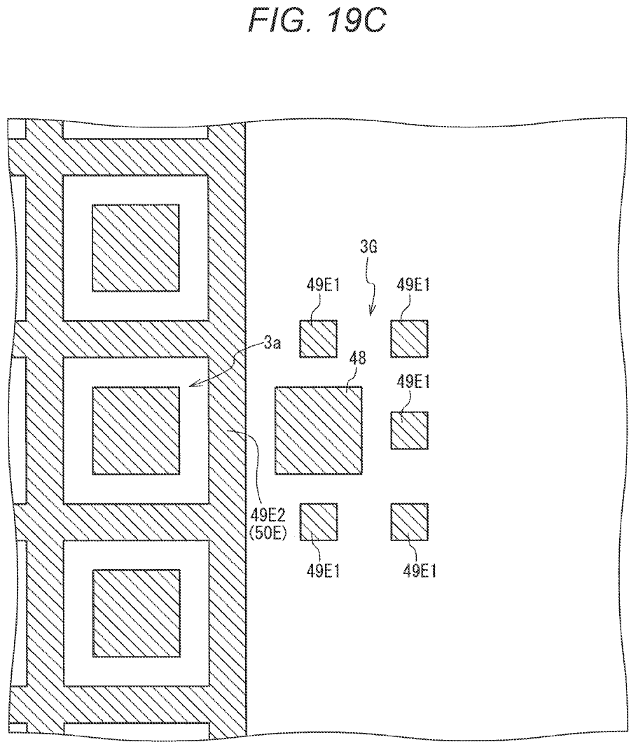

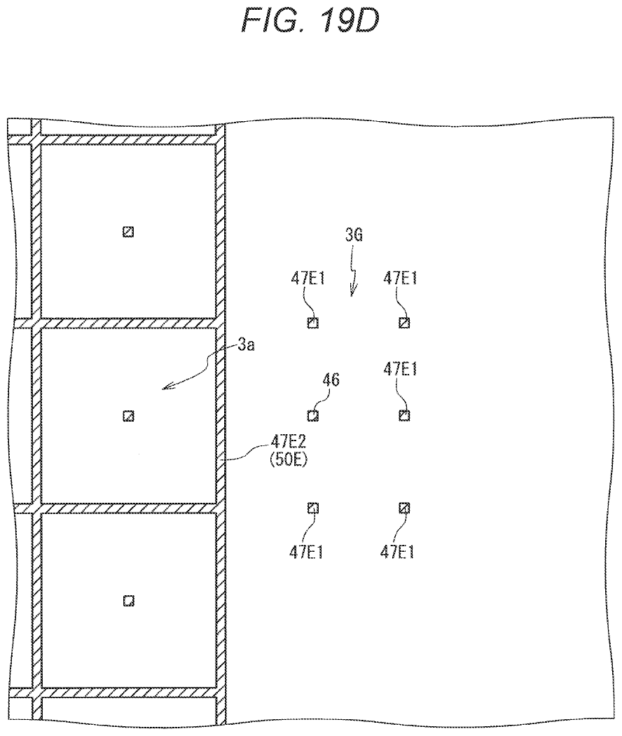

Hereinafter, the pixel 3G will be described. As depicted in FIG. 18 and cross-sectional views of FIGS. 19A to 19D, regarding the pixel 3G, the light shielding wall 50E is provided only between the interlayer insulating film 60 corresponding to the pixel 3G and the interlayer insulating film 60 corresponding to the pixel 3a adjacent to the pixel 3G, and conventional through hole electrodes or pads are provided in other positions. That is, regarding the pixel 3G, the contact electrode wirings 24E2, the first connection wirings 26E2, the second connection wiring 49E2, and the second via electrode wiring 47E2 are provided only between the interlayer insulating film 60 corresponding to the pixel 3G and the interlayer insulating film corresponding to the pixel 3a adjacent to the pixel 3G, and the conventional contact electrodes 24E1, first connection pad 26E1, second connection pad 49E1, and second via electrode 47E1 are provided at other positions.

<Effect>

In the photodetector 1 according to the second modification of the second embodiment, the pixel 3G can be used as a reference pixel. In the distance measurement by the APD element 6, first, a laser is caused to emit light to irradiate a subject with light, and light reflected by the subject and returned is detected by the APD element 6. Then, the distance to the subject is obtained on the basis of the time from the emission of the laser to the detection of the returned light and the speed of the light. However, when the laser and the circuit of the APD element 6 are synchronized to measure time, the APD element 6 may detect stray light generated at the time of laser emission and measure the distance with the stray light. Accordingly, a reference pixel for detecting stray light may be provided to detect the timing at which the laser emits light. Such a reference pixel can detect stray light incident from a direction intersecting with the thickness direction of the sensor chip 2, for example, a lateral direction or an oblique lateral direction by having a structure including conventional through hole electrodes or pads. As described above, by leaving the conventional structure for the pixel 3G of the part of the pixels 3, the pixel can be used as the reference pixel.

### Third Embodiment

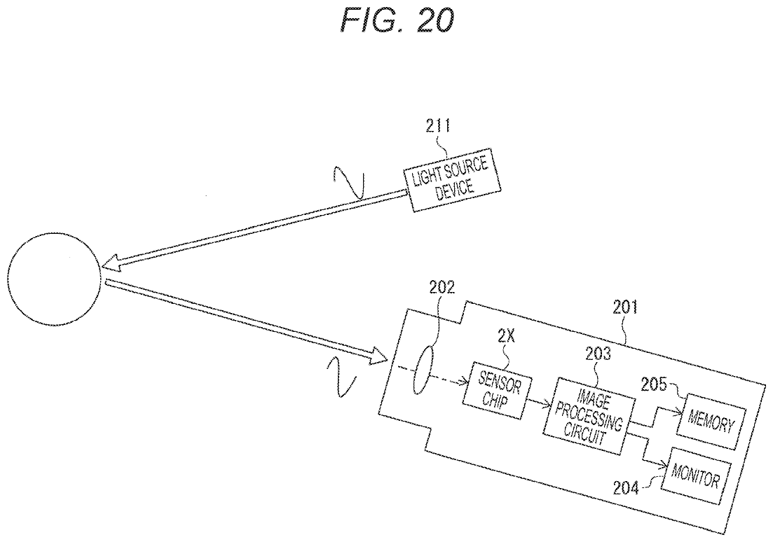

In the third embodiment, a configuration example of an electronic device will be described. As depicted in FIG. 20, a distance image device 201 as an electronic device includes an optical system 202, a sensor chip 2X, an image processing circuit 203, a monitor 204, and a memory 205. The distance image device 201 can acquire a distance image according to the distance to the subject by receiving light (modulated light or pulsed light) projected from a light source apparatus 211 toward the subject and reflected on the surface of the subject.

The optical system 202 includes one or more optical lenses, guides image light (incident light) from a subject to the sensor chip 2X, and forms an image on a light receiving surface (sensor unit) of the sensor chip 2X.

As the sensor chip 2X, the sensor chip 2 on which the photodetector 1 of the first embodiment described above is mounted is applied, and a distance signal indicating a distance obtained from a light reception signal (APD OUT) output from the sensor chip 2X is supplied to the image processing circuit 203.

The image processing circuit 203 performs image processing of constructing a distance image on the basis of the distance signal supplied from the sensor chip 2X, and the distance image (image data) obtained by the image processing is supplied to and displayed on the monitor 204 or supplied to and stored (recorded) in the memory 205.

In the distance image device 201 configured as described above, by applying the sensor chip 2 described above, it is possible to calculate the distance to the subject on the basis of only the light reception signal from the pixel 3 with high stability, and generate a highly accurate distance image. That is, the distance image device 201 can acquire a more accurate distance image.

Note that, although the sensor chip 2 on which the photodetector 1 according to the first embodiment of the present technology is mounted is applied as the sensor chip 2X, the sensor chip 2 on which the photodetector 1 according to any one of the first to fourth modifications of the first embodiment, the second embodiment, and the first and second modifications thereof is mounted may be applied.

<Use Examples of Image Sensor>

The sensor chip 2 (image sensor) described above can be used in various cases for sensing light such as visible light, infrared light, ultraviolet light, and X-ray as described below, for example.
A device that captures an image to be used for viewing, such as a digital camera and a portable device with a camera function.
A device for traffic purpose such as an in-vehicle sensor that captures images of the front, rear, surroundings, interior and the like of an automobile, a surveillance camera for monitoring traveling vehicles and roads, and a ranging sensor which measures a distance between vehicles and the like for safe driving such as automatic stop, recognition of a driver's condition and the like.
A device used for home electric appliances such as a television, a refrigerator, and an air conditioner in order to capture an image of a gesture of a user and perform device operation according to the gesture
A device for medical and health care use such as an endoscope and a device that performs angiography by receiving infrared light
A device for security use such as a security monitoring camera and an individual authentication camera
A device for beauty care such as a skin condition measuring device that captures an image of skin and a microscope that captures an image of scalp
A device for sporting use such as an action camera and a wearable camera for sporting use and the like
A device for agricultural purpose such as a camera for monitoring conditions of fields and crops

### Other Embodiments

While the present technology has been described above by way of the first to third embodiments and the modifications of the embodiments, it should not be understood that the description and drawings constituting a part of this disclosure limit the present technology. Various alternative embodiments, examples, and operation techniques will be apparent to those skilled in the art from this disclosure.

Furthermore, the technical ideas described in the first to third embodiments and the modifications of the embodiments may be combined with each other. For example, various combinations according to the respective technical ideas are possible, such as applying the technical idea of including at least one of the first portion extending along the row direction or the second portion extending along the column direction, which are described in the second embodiment and the first and second modifications of the second embodiment, to the light shielding walls according to the first embodiment and the first to fourth modifications of the first embodiment, and the like.

Furthermore, in the first to third embodiments described above, the first portion 501 and the components thereof and the second portion 502 and the components thereof are connected as depicted in the cross-sectional view, but may not be connected. For example, there may be a gap between the first portion 501 and its components and the second portion 502 and its components to such an extent that the influence of crosstalk can be generally suppressed, for example, equal to or less than about several percent with respect to the whole.

Furthermore, the first portion 501 and the components thereof continuously extend along the row direction as depicted in the cross-sectional view, but may include a discontinuous portion. For example, in the first portion 501 and the components thereof, there may be discontinuous portions to such an extent that the influence of crosstalk can be generally suppressed, for example, equal to or less than about several percent with respect to the whole. Similarly, the second portion 502 and the components thereof continuously extend along the column direction as depicted in the cross-sectional view, but may include a discontinuous portion. For example, in the second portion 502 and the components thereof, there may be discontinuous portions to such an extent that the influence of crosstalk can be generally suppressed, for example, equal to or less than about several percent with respect to the whole.

Furthermore, for example, the first connection pad 25 and the second connection pad 48 have different shapes in FIG. 4, but may have the same shape. The first connection pad 25 may have the same shape as the second connection pad 48, or the second connection pad 48 may have the same shape as the first connection pad 25.

<1. Application Example to Mobile Body>

The technology according to the present disclosure (the present technology) can be applied to various products. For example, the technology according to the present disclosure may be achieved as a device mounted on any type of mobile body such as an automobile, an electric vehicle, a hybrid electric vehicle, a motorcycle, a bicycle, a personal mobility, an airplane, a drone, a boat, a robot, and the like.

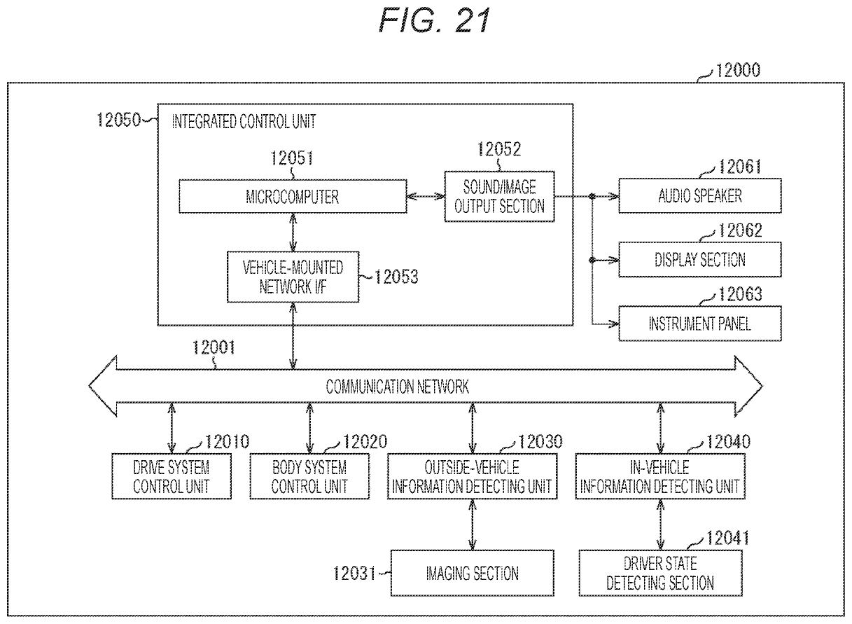

FIG. 21 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 21, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are depicted as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

Furthermore, the microcomputer 12051 can output a control command to the body system control unit 12020 on the basis of information about the outside of the vehicle, the information being acquired by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 21, an audio speaker 12061, a display section 12062, and an instrument panel 12063 are depicted as the output device. The display section 12062 may, for example, include at least one of an on-board display and a head-up display.

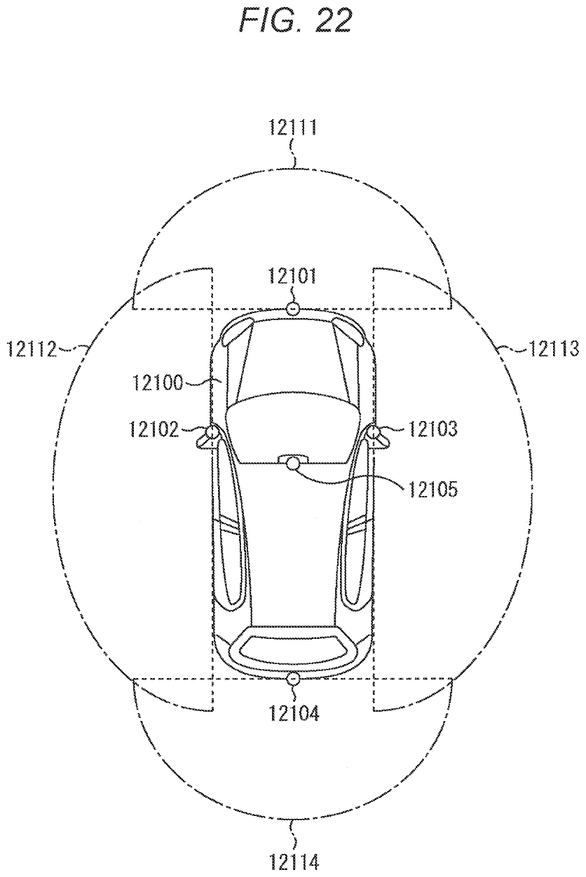

FIG. 22 is a diagram depicting an example of the installation position of the imaging section 12031.

In FIG. 22, the vehicle 12100 includes imaging sections 12101, 12102, 12103, 12104, and 12105 as the imaging section 12031.

The imaging sections 12101, 12102, 12103, 12104, and 12105 are provided, for example, at positions such as a front nose, a sideview mirror, a rear bumper, a back door, and an upper part of a windshield in the cabin of the vehicle 12100. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The forward images obtained by the imaging sections 12101 and 12105 are used mainly to detect a preceding vehicle, a pedestrian, an obstacle, a signal, a traffic sign, a lane, or the like.

Incidentally, FIG. 22 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

The example of the vehicle control system to which the technology according to the present disclosure can be applied has been described above. The technology according to the present disclosure can be applied to the imaging section 12031 among the configurations described above. Specifically, the photodetector 1 of FIG. 1 can be applied to the imaging section 12031. By applying the technology according to the present disclosure to the imaging section 12031, it is possible to reduce erroneous measurement and to more accurately perform distance measurement.

<2. Application Example to Endoscopic Surgery System>

The technology according to the present disclosure (the present technology) can be applied to various products. For example, the technology according to the present disclosure may be applied to an endoscopic surgery system.

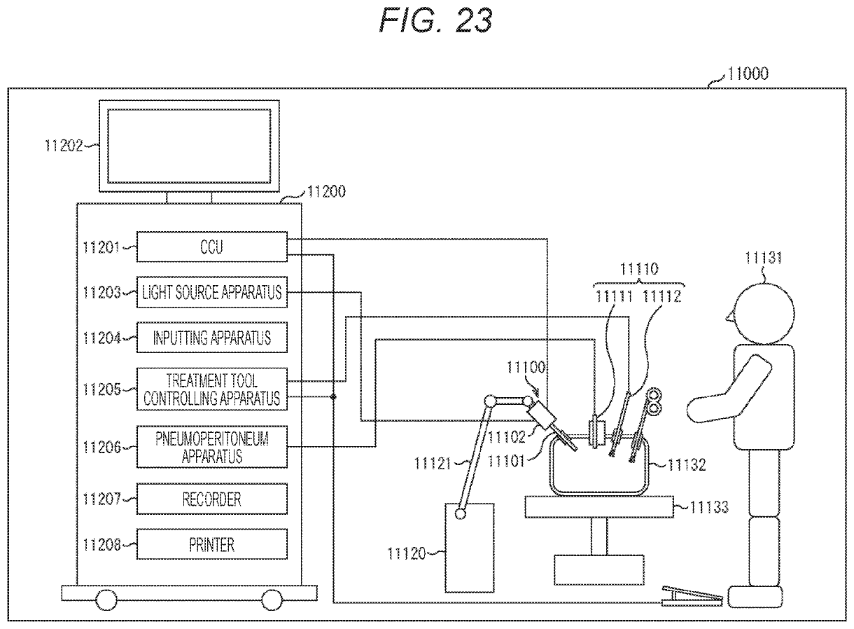

FIG. 23 is a view depicting an example of a schematic configuration of an endoscopic surgery system to which the technology according to an embodiment of the present disclosure (present technology) can be applied.

In FIG. 23, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region or the like to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

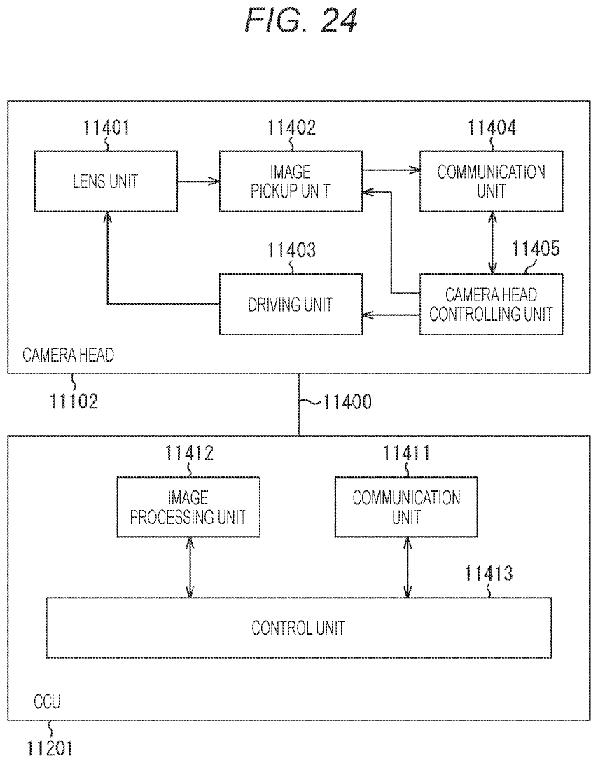

FIG. 24 is a block diagram depicting an example of a functional configuration of the camera head 11102 and the CCU 11201 depicted in FIG. 23.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The image pickup unit 11402 includes an image pickup element. The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

The example of the endoscopic surgery system to which the technology according to the present disclosure can be applied has been described above. The technology according to the present disclosure can be applied to the image pickup unit 11402 among the configurations described above. Specifically, the photodetector 1 of FIG. 1 can be applied to the image pickup unit 10402. By applying the technology according to the present disclosure to the image pickup unit 10402, it is possible to reduce erroneous measurement and to more accurately perform distance measurement.

Note that, here, the endoscopic surgery system has been described as an example, but the technology according to the present disclosure may be applied to other, for example, microscopic surgery systems and the like.

As described above, it is a matter of course that the present technology includes various embodiments and the like not described herein. Therefore, the technical scope of the present technology is defined only by the matters used to define the invention described in the claims considered appropriate from the above description.

Furthermore, the effects described herein are merely illustrative and not restrictive, and may have additional effects.

Note that the present technology may have the following configurations.
(1)

A photodetector including:
a first semiconductor substrate including a first semiconductor layer in which a plurality of photoelectric conversion sections is provided in an array along a row direction and a column direction, and a first wiring layer provided on a main surface side of the first semiconductor layer;
a second semiconductor substrate including a second semiconductor layer provided with an active element and a second wiring layer provided on a main surface side of the second semiconductor layer, the second wiring layer being overlapped with and joined to the first wiring layer; and
a light shielding wall that divides at least one of at least a part of an interlayer insulating film of the first wiring layer or at least a part of a portion of an interlayer insulating film of the second wiring layer on a side of the first semiconductor substrate into respective portions corresponding to a first photoelectric conversion section and a second photoelectric conversion section adjacent to each other of a plurality of the photoelectric conversion sections.
(2)

The photodetector according to (1), in which the light shielding wall does not pass light in a wavelength band that is photoelectrically convertible by the photoelectric conversion sections.
(3)

The photodetector according to (1) or (2), in which the light shielding wall includes at least one of a first portion extending along the row direction or a second portion extending along the column direction.
(4)

The photodetector according to (3), in which the light shielding wall includes only the second portion extending along the column direction.
(5)

The photodetector according to (4), in which a plurality of the photoelectric conversion sections provided in an array is applied with a bias voltage in units of rows, and rows to which the bias voltage is applied are sequentially selected along a column direction.
(6)

The photodetector according to any one of (1) to (5), in which the light shielding wall penetrates the interlayer insulating film of the first wiring layer.
(7)

The photodetector according to any one of (1) to (6), in which the light shielding wall penetrates a portion of the interlayer insulating film of the second wiring layer on a side of the first semiconductor substrate.
(8)

The photodetector according to any one of (1) to (7), in which one end of the light shielding wall in a thickness direction of the first semiconductor substrate is connected to one of the photoelectric conversion sections.
(9)

The photodetector according to (8), in which the light shielding wall supplies a bias voltage from the second semiconductor substrate to the photoelectric conversion sections.
(10)

The photodetector according to any one of (1) to (9), in which
the light shielding wall includes:
a first connection wiring provided in the first wiring layer and facing a surface opposite to a surface on a side of the first semiconductor layer among surfaces of the first wiring layer; and
a second connection wiring provided in the second wiring layer, facing a surface opposite to a surface on a side of the second semiconductor layer among surfaces of the second wiring layer, and joined to the first connection wiring.
(11)

The photodetector according to (3), in which
the photoelectric conversion sections include an avalanche photodiode,
the photodetector includes a reading electrode that outputs carriers from the avalanche photodiode to the second semiconductor substrate for each of the photoelectric conversion sections, and
the light shielding wall includes both the first portion and the second portion, supplies a bias voltage to the avalanche photodiode, and surrounds the reading electrode by the first portion and the second portion.
(12)

The photodetector according to (4), in which
the photoelectric conversion sections each include an avalanche photodiode,
the photodetector includes a reading electrode that outputs carriers from the avalanche photodiode to the second semiconductor substrate for each of the photoelectric conversion sections,
the light shielding wall supplies a bias voltage to the avalanche photodiode, and divides the reading electrodes adjacent to each other in the row direction by the second portion.
(13)

An electronic device including:
a photodetector; and
an optical system that forms an image of image light from a subject on the photodetector, in which
the photodetector includes:
a first semiconductor substrate including a first semiconductor layer in which a plurality of photoelectric conversion sections is provided in an array along a row direction and a column direction, and a first wiring layer provided on a main surface side of the first semiconductor layer;
a second semiconductor substrate including a second semiconductor layer provided with an active element and a second wiring layer provided on a main surface side of the second semiconductor layer, the second wiring layer being overlapped with and joined to the first wiring layer; and
a light shielding wall that divides at least one of at least a part of an interlayer insulating film of the first wiring layer or at least a part of a portion of an interlayer insulating film of the second wiring layer on a side of the first semiconductor substrate into respective portions corresponding to a first photoelectric conversion section and a second photoelectric conversion section adjacent to each other of a plurality of the photoelectric conversion sections.

The scope of the present technology is not limited to the illustrated and described embodiments, and includes all embodiments that provide effects equivalent to the effects intended to be provided by the present technology. Moreover, the scope of the present technology is not limited to the combinations of the features of the invention defined by the claims, and may be defined by any desired combination of specific features among all the disclosed features.

### REFERENCE SIGNS LIST

1 Photodetector
2 Sensor chip
2A Pixel region
2B Peripheral region
3, 3a, 3G Pixel
4 Electrode pad
5 Bias voltage applying section
6 APD element
7 Quenching resistance element
8 Inverter
10 First semiconductor substrate
11 First semiconductor layer
12 Photoelectric conversion section
13 Separation portion
14 Well region
15 Light absorption section
16 Multiplication section
16a First electrode region
16b Second electrode region
16c Avalanche multiplication region
17 First contact region
18 Second contact region
19 Charge accumulation region
21, 21B, 21C, 21E, 21F First wiring layer
22 First interlayer insulating film
23 Contact electrode
24, 24E2 Contact electrode wiring
24E1 Contact electrode
25B, 25D First connection pad
26, 26B, 26E2 First connection wiring
26E1 First connection pad
27a Reflective pad
27b First wiring
27bF1 First electrode pad
27bF2 First wiring
28a First via electrode
28b First via electrode wiring
28bF1 First via electrode
28bF2 First via electrode wiring
30 Second semiconductor substrate
31 Second semiconductor layer
32 MOSFET
41, 41A, 41E, 41G Second wiring layer
42 Second interlayer insulating film
43 Wiring
44, 45 Electrode pad
46 Second via electrode
47 Second via electrode wiring
47E1 Second via electrode
47E2 Second via electrode wiring
48, 48A Second connection pad
48A Second connection pad
49E1 Second connection pad
49E2 Second connection wiring
49, 49A Second connection wiring
50A, 50B, 50C, 50E, 50F, 50G, 51, 52 Light shielding wall
50a End portion
58 Second connection wiring
60C, 61, 62, 63, 64, 65, 66 Interlayer insulating film
71 Planarization film
72 Microlens layer
100 Electronic device
101 Photodetector
102 Optical system
103 Shutter device
104 Driving circuit
105 Signal processing circuit
106 Incident light
201 Distance image device

1. A photodetector comprising:
a first semiconductor substrate including a first semiconductor layer in which a plurality of photoelectric conversion sections is provided in an array along a row direction and a column direction, and a first wiring layer provided on a main surface side of the first semiconductor layer;
a second semiconductor substrate including a second semiconductor layer provided with an active element and a second wiring layer provided on a main surface side of the second semiconductor layer, the second wiring layer being overlapped with and joined to the first wiring layer; and
a light shielding wall that divides at least one of at least a part of an interlayer insulating film of the first wiring layer or at least a part of a portion of an interlayer insulating film of the second wiring layer on a side of the first semiconductor substrate into respective portions corresponding to a first photoelectric conversion section and a second photoelectric conversion section adjacent to each other of a plurality of the photoelectric conversion sections.

2. The photodetector according to claim 1, wherein the light shielding wall does not pass light in a wavelength band that is photoelectrically convertible by the photoelectric conversion sections.

3. The photodetector according to claim 1, wherein the light shielding wall includes at least one of a first portion extending along the row direction or a second portion extending along the column direction.

4. The photodetector according to claim 3, wherein the light shielding wall includes only the second portion extending along the column direction.

5. The photodetector according to claim 4, wherein a plurality of the photoelectric conversion sections provided in an array is applied with a bias voltage in units of rows, and rows to which the bias voltage is applied are sequentially selected along a column direction.

6. The photodetector according to claim 1, wherein the light shielding wall penetrates the interlayer insulating film of the first wiring layer.

7. The photodetector according to claim 1, wherein the light shielding wall penetrates a portion of the interlayer insulating film of the second wiring layer on a side of the first semiconductor substrate.

8. The photodetector according to claim 1, wherein one end of the light shielding wall in a thickness direction of the first semiconductor substrate is connected to one of the photoelectric conversion sections.

9. The photodetector according to claim 8, wherein the light shielding wall supplies a bias voltage from the second semiconductor substrate to the photoelectric conversion sections.

10. The photodetector according to claim 1, wherein
the light shielding wall includes:
a first connection wiring provided in the first wiring layer and facing a surface opposite to a surface on a side of the first semiconductor layer among surfaces of the first wiring layer; and
a second connection wiring provided in the second wiring layer, facing a surface opposite to a surface on a side of the second semiconductor layer among surfaces of the second wiring layer, and joined to the first connection wiring.

11. The photodetector according to claim 3, wherein
the photoelectric conversion sections each include an avalanche photodiode,
the photodetector comprises a reading electrode that outputs carriers from the avalanche photodiode to the second semiconductor substrate for each of the photoelectric conversion sections, and
the light shielding wall includes both the first portion and the second portion, supplies a bias voltage to the avalanche photodiode, and surrounds the reading electrode by the first portion and the second portion.

12. The photodetector according to claim 4, wherein
the photoelectric conversion sections each include an avalanche photodiode,
the photodetector comprises a reading electrode that outputs carriers from the avalanche photodiode to the second semiconductor substrate for each of the photoelectric conversion sections,
the light shielding wall supplies a bias voltage to the avalanche photodiode, and divides the reading electrodes adjacent to each other in the row direction by the second portion.

13. An electronic device comprising:
a photodetector; and
an optical system that forms an image of image light from a subject on the photodetector, wherein
the photodetector includes:
a first semiconductor substrate including a first semiconductor layer in which a plurality of photoelectric conversion sections is provided in an array along a row direction and a column direction, and a first wiring layer provided on a main surface side of the first semiconductor layer;
a second semiconductor substrate including a second semiconductor layer provided with an active element and a second wiring layer provided on a main surface side of the second semiconductor layer, the second wiring layer being overlapped with and joined to the first wiring layer; and
a light shielding wall that divides at least one of at least a part of an interlayer insulating film of the first wiring layer or at least a part of a portion of an interlayer insulating film of the second wiring layer on a side of the first semiconductor substrate into respective portions corresponding to a first photoelectric conversion section and a second photoelectric conversion section adjacent to each other of a plurality of the photoelectric conversion sections.
